(19) United States
(12) Patent Application Publication
(10) Pub. No.: US 2013/0234121 A1
(43) Pub. Date: Sep. 12, 2013

(54) METHOD OF MANUFACTURING ORGANIC EL APPARATUS, ORGANIC EL APPARATUS, AND ELECTRONIC EQUIPMENT

(71) Applicant: SEIKO EPSON CORPORATION, Tokyo (JP)

(72) Inventor: Takuya SONOYAMA, Fujimi-machi (JP)

(73) Assignee: SEIKO EPSON CORPORATION, Tokyo (JP)

(21) Appl. No.: 13/777,589

(22) Filed: Feb. 26, 2013

(30) Foreign Application Priority Data
Mar. 8, 2012 (JP) 2012-051322
Dec. 7, 2012 (JP) 2012-267971

(51) Int. Cl. H01L 51/50; H01L 51/56

(52) U.S. Cl. CPC H01L 51/5012; H01L 51/56
USPC 257/40; 438/34

(57) ABSTRACT

A manufacturing method of an organic EL apparatus according to the present application example is provided with a plurality of light emitting elements having a light emitting layer between an anode and a cathode, and includes: forming the light emitting layer using a liquid phase process, and forming an intermediate layer between the light emitting layer and the cathode in contact with the light emitting layer using a gas phase process, in which the intermediate layer includes a low molecular weight host material included in the light emitting layer.

### BACKGROUND

### 1. Technical Field

The present invention relates to a method of manufacturing an organic electroluminescence (EL) apparatus, an organic EL apparatus and electronic equipment.

The above-described organic EL apparatus has a structure in which a light emitting layer formed of organic light emitting material is pinched between an anode and a cathode. As the method of manufacturing an organic EL apparatus, for example, as described in JP-A-2001-76874, a method of manufacturing, which employs the mutual merits of a printing method and a vapor deposition method, is used.

For example, first, in consideration of the coating separation property corresponding to the light emission colors of red (R), green (G), and blue (B), forming up to a light emitting layer is performed using a printing method with high material usage efficiency. Next, a buffer layer formed of organic material is formed using a vapor deposition method. For the organic material, the use of an electron injection material is preferable in order to ensure the electron injection property and the hole blocking property with respect to the light emitting layer. In this manner, it is possible to efficiently form an organic EL element (light emitting element) having a long light emitting lifespan.

However, since the transportation of electrons to the light emitting layer cannot be performed smoothly without obtaining sufficient affinity at the interface between the light emitting layer formed by the printing method and the buffer layer formed by the vapor deposition method, there have been problems such as the generation of dark spots and the reduction of the light emitting area. In addition, even if the dark spots are improved by arranging a film for increasing electron transportability between the light emitting layer and the buffer layer, there is a problem in that it is not possible to efficiently emit light.

### SUMMARY

The invention can be realized in the following forms or application examples.

### Application Example 1

A manufacturing method of an organic EL apparatus according to the present application example provided with a plurality of light emitting elements having a light emitting layer between an anode and a cathode, includes: forming the light emitting layer using a liquid phase process, and forming an intermediate layer between the light emitting layer and the cathode in contact with the light emitting layer using a gas phase process, in which the intermediate layer includes a low molecular weight host material included in the light emitting layer.

According to the present application example, between a light emitting layer formed by a liquid phase process and a cathode formed by a gas phase process, an intermediate layer formed by a gas phase process and including a low molecular weight host material included in the light emitting layer is arranged in contact with the light emitting layer. Accordingly, in comparison with a case of pinching an electron transporting layer, for example, formed by a gas phase process between the light emitting layer, which is a coating film, and the cathode, since the intermediate layer has excellent affinity with respect to the light emitting layer, it is possible to smoothly perform transportation of the electrons from the cathode to the light emitting layer. Thus, it is possible to suppress the generation of dark spots and the reduction of the light emitting area and it is possible to manufacture an organic EL apparatus having excellent light emitting efficiency. Here, the light emitting efficiency indicates the current efficiency or the external quantum efficiency.

### Application Example 2

A manufacturing method of an organic EL apparatus according to the present application example provided with a first light emitting element having a first light emitting layer between a first anode and a shared cathode, and a second light emitting element having a second light emitting layer between a second anode and the shared cathode, includes: forming the first light emitting layer using a liquid phase process, forming the second light emitting layer, which straddles the first light emitting element and the second light emitting element, between the first light emitting layer and the shared cathode and between the second anode and shared cathode using a gas phase process, and forming an intermediate layer, which straddles the first light emitting element and the second light emitting element, between the first light emitting layer and the second light emitting layer and in contact with the first light emitting layer using the gas phase process, in which the intermediate layer includes a low molecular weight host material included in the first light emitting layer.

According to the present application example, in the first light emitting element, since the intermediate layer has excellent affinity with respect to the first light emitting layer even when there are the first light emitting layer formed by a liquid phase process and the second light emitting layer formed by a gas phase process between the first anode and the shared cathode, it is possible to make the first light emitting layer selectively emit light. In other words, it is possible to provide a method of manufacturing an organic EL apparatus, which is able to be efficiently manufactured and in which the first light emitting layer emits light in the first light emitting element and the second light emitting layer emits light in the second light emitting element, without separately coating the first light emitting layer and the second light emitting layer, by using a liquid phase process and a gas phase process.

### Application Example 3

The method of manufacturing an organic EL apparatus according to the application examples described above may further include: forming a hole injecting layer between the first anode and the first light emitting layer and between the second anode and the intermediate layer, in contact with the first anode and the second anode, using the liquid phase process, forming a first hole transporting layer between the hole injecting layer and the first light emitting layer and in contact with the hole injecting layer, using the liquid phase process, and forming a second hole transporting layer, which straddles the first light emitting element and the second light emitting element, between the intermediate layer and the second light emitting layer, using the gas phase process, in which the second light emitting layer may be formed in contact with the second hole transporting layer.

According to this method, since, in the first light emitting layer formed by the liquid phase process, a first hole transporting layer formed by the same liquid phase process is in contact therewith, and in the second light emitting layer formed by the gas phase process, a second hole transporting layer formed by the same gas phase process is in contact therewith, holes are injected into the respective light emitting layers with high efficiency. Accordingly, it is possible to realize high light emitting efficiency in the first light emitting layer and the second light emitting layer.

### Application Example 4

The method of manufacturing an organic EL apparatus according to the application examples described above may further include: forming a carrier adjusting layer between the intermediate layer and the second hole transporting layer in contact with the intermediate layer, using the gas phase process, in which the carrier adjusting layer may include a metal compound having an electron transporting property.

According to this method, since, in the first light emitting element, the carrier adjusting layer formed in contact with the intermediate layer has an electron transporting property even when there are the intermediate layer and the second light emitting layer between the first light emitting layer and the shared cathode, it is possible to efficiently transport electrons to the first light emitting layer and it is possible to realize a high light emitting efficiency in the first light emitting layer.

### Application Example 5

In the method of manufacturing an organic EL apparatus according to the application examples described above, the metal compound may be cesium carbonate.

According to this method, it is possible to form a carrier adjusting layer having an excellent electron transporting property.

### Application Example 6

In the method of manufacturing an organic EL apparatus according to the application examples described above, the second hole transporting layer may include a hole transporting material of low molecular weight and the method may further include: forming a third hole transporting layer including a hole transporting material of low molecular weight between the second anode of the second light emitting element and the intermediate layer and in contact with the hole injecting layer, using the liquid phase process, in which the step of forming the third hole transporting layer may be performed after the step of forming the first light emitting layer.

According to this method, since the third hole transporting layer including the hole transporting material of low molecular weight included in the second hole transporting layer is formed between the hole injecting layer of the second light emitting element and the intermediate layer, the transporting property of the holes to the second light emitting layer is further improved. Accordingly, it is possible to realize high light emitting efficiency in the second light emitting layer of the second light emitting element. In addition, since the forming of the third hole transporting layer is performed by the liquid phase process after the first light emitting layer is formed, in comparison with a case where the third hole transporting layer is formed before the first light emitting layer is formed, it is possible to prevent a decrease in the functions of the third hole transporting layer due to the hole transporting material of low molecular weight aggregating due to a drying process such as heating during the forming of the first light emitting layer.

### Application Example 7

In the method of manufacturing an organic EL apparatus according to the application examples described above, a third light emitting element having a third light emitting layer between the third anode and the shared cathode is further provided, and the method may further include: forming the third light emitting layer, using the liquid phase process, in which the second light emitting layer may be formed between the first light emitting layer and the shared cathode and between the third light emitting layer and the shared cathode, and the first light emitting layer, the second light emitting layer, and the third light emitting layer respectively indicate different light emission colors.

According to this method, it is possible to manufacture an organic EL apparatus which has excellent light emitting efficiency and which is able to make the first light emitting layer, the second light emitting layer, and the third light emitting layer selectively emit light, respectively.

### Application Example 8

In the method of manufacturing an organic EL apparatus according to the application examples described above, the first light emitting layer indicating a red light emission color may be formed, the second light emitting layer indicating a blue light emission color may be formed, and the third light emitting layer indicating a green light emission color may be formed.

According to this method, it is possible to manufacture an organic EL apparatus which has excellent light emitting efficiency and is capable of a full color display.

### Application Example 9

In the method of manufacturing an organic EL apparatus according to the application examples described above, a thickness of the intermediate layer may be 1 nm or more and 5 nm or less.

According to this method, since the thickness of the intermediate layer is set within the above-described range, it is possible to suppress an increase in the driving voltage or a decrease in the light emitting efficiency caused by forming the intermediate layer between the light emitting layer and the cathode or the shared cathode.

### Application Example 10

In the method of manufacturing an organic EL apparatus according to the application examples described above, the low molecular weight host material may have an electron transporting property.

According to this method, since the intermediate layer has an electron transporting property, it is possible to more smoothly move electrons from the cathode or the shared cathode to the light emitting layer, whereby it is possible the improve the light emitting efficiency.

### Application Example 11

In the method of manufacturing an organic EL apparatus according to the application examples described above, the liquid phase process may be a liquid droplet discharge method discharging a functional liquid including a functional layer forming material as the liquid droplets.

According to this method, since it is possible to discharge with high precision a predetermined amount of the functional liquid in a desired region as the liquid droplets, it is possible to manufacture with high efficiency an organic EL apparatus having the desired light emitting characteristics.

### Application Example 12

An organic EL apparatus according to the present application example includes, on a substrate, an anode, a cathode which is a vapor deposited film, a light emitting layer which is a coating film between the anode and the cathode, and an intermediate layer, which is a vapor deposited film including a low molecular weight host material included in the light emitting layer, between the light emitting layer and the cathode and in contact with the light emitting layer.

According to the present application example, between the light emitting layer which is an inked film and the cathode which is a vapor deposited film, an intermediate layer which is a vapor deposited film and which includes a low molecular weight host material included in the light emitting layer is arranged in contact with the light emitting layer. Accordingly, in comparison with a case of pinching, for example, an electron transporting layer which is a vapor deposited film between the light emitting layer, which is a coating film, and the cathode, which is a vapor deposited film, since the intermediate layer has excellent affinity with respect to the light emitting layer, it is possible to smoothly perform transportation of the electrons from the cathode to the light emitting layer. Thus, it is possible to suppress the generation of dark spots and the reduction of the light emitting area and it is possible to provide an organic EL apparatus having excellent light emitting characteristics.

### Application Example 13

An organic EL apparatus according to the present application example includes, on a substrate, a first light emitting element having a first light emitting layer which is a coating film and a second light emitting layer which is a vapor deposited film between a first anode and a shared cathode which is a vapor deposited film, a second light emitting element having a second light emitting layer between the second anode and the shared cathode, and an intermediate layer, which is a vapor deposited film including a low molecular weight host material included in the first light emitting layer and which is formed to straddle the first light emitting element and the second light emitting element in contact with the first light emitting layer between the first light emitting layer and the second light emitting layer and between the second anode and the second light emitting layer.

According to the present application example, in the first light emitting element, since the intermediate layer has excellent affinity with respect to the first light emitting layer even when there are the first light emitting layer which is a coating film and the second light emitting layer which is a vapor deposited film between the first anode and the shared cathode, it is possible to make the first light emitting layer selectively emit light. In other words, it is possible to provide an organic EL apparatus which is able to be efficiently manufactured and in which the first light emitting layer emits light in the first light emitting element and the second light emitting layer emits light in the second light emitting element, without separately coating the first light emitting layer and the second light emitting layer, by using a liquid phase process and a gas phase process.

### Application Example 14

The organic EL apparatus according to the above-described application examples may further include a hole injecting layer, which is a coating film, between the first anode and the first light emitting layer and between the second anode and the intermediate layer in contact with the first anode and the second anode, a first hole transporting layer, which is a coating film, between the hole injecting layer and the first light emitting layer in contact with the hole injecting layer, and a second hole transporting layer, which is a vapor deposited film, between the intermediate layer and the second light emitting layer.

According to this configuration, since the first light emitting layer which is a coating film contacts the first hole transporting layer which is the same coating film, and the second light emitting layer which is a vapor deposited film contacts the second hole transporting layer which is the same vapor deposited film, holes are injected into the respective light emitting layers with high efficiency. Accordingly, it is possible to realize high light emitting efficiency in the first light emitting layer and the second light emitting layer.

### Application Example 15

The organic EL apparatus according to the above-described application examples may further include a carrier adjusting layer, which is a vapor deposited film, between the intermediate layer and the second hole transporting layer in contact with the intermediate layer, in which the carrier adjusting layer may include a metal compound having an electron transporting property.

According to this configuration, since, in the first light emitting element, the carrier adjusting layer formed in contact with the intermediate layer has an electron transporting property even when there are the intermediate layer and the second light emitting layer between the first light emitting layer and the shared cathode, it is possible to efficiently transport electrons to the first light emitting layer and it is possible to realize a high light emitting efficiency in the first light emitting layer.

### Application Example 16

The organic EL apparatus according to the above-described application examples, in which the second hole transporting layer includes a low molecular weight hole transporting material, may further include: a third hole transporting layer including the low molecular weight hole transporting material, which is a coating film, between the second anode of the second light emitting element and the intermediate layer in contact with the second anode.

According to this configuration, since the third hole transporting layer including the hole transporting material of low molecular weight included in the second hole transporting layer is arranged between the hole injecting layer of the second light emitting element and the intermediate layer, the transporting property of the holes to the second light emitting layer is further improved. Accordingly, it is possible to realize high light emitting efficiency in the second light emitting layer of the second light emitting element.

### Application Example 17

The organic EL apparatus according to the above-described application examples may further include a third light emitting element having a third light emitting layer, which is a coating film, between the third anode and the shared cathode, in which the second light emitting layer may be formed between the first light emitting layer and the shared cathode and between the third light emitting layer and the shared cathode, and the first light emitting layer, the second light emitting layer and the third light emitting layer may respectively indicate different light emission colors.

According to this configuration, it is possible to provide an organic EL apparatus which has excellent light emitting efficiency and which is able to make the first light emitting layer, the second light emitting layer, and the third light emitting layer selectively emit light, respectively.

### Application Example 18

In the organic EL apparatus according to the above-described application examples, the first light emitting layer of the first light emitting element may indicate a red light emission color, the second light emitting layer of the second light emitting element may indicate a blue light emission color, and the third light emitting layer of the third light emitting element may indicate a green light emission color.

According to this configuration, it is possible to provide an organic EL apparatus which has excellent light emitting efficiency and is capable of a full color display.

### Application Example 19

Electronic equipment according to the present application example includes an organic EL apparatus manufactured using the method of manufacturing an organic EL apparatus according to the above-described application examples.

According to this configuration, since an organic EL apparatus which is able to be manufactured efficiently and which has excellent light emitting efficiency is provided, it is possible to provide electronic equipment having an excellent cost performance.

### Application Example 20

Electronic equipment according to the present application example includes an organic EL apparatus according to the above-described application examples.

According to this configuration, since an organic EL apparatus which has excellent light emitting efficiency is provided, it is possible to provide electronic equipment with a good appearance.

### BRIEF DESCRIPTION OF THE DRAWINGS

The invention will be described with reference to the accompanying drawings, wherein like numbers reference like elements.

FIG. 1 is an equivalent circuit diagram showing an electrical configuration of an organic EL apparatus of a first embodiment.

FIG. 2 is a schematic plan view showing a configuration of the organic EL apparatus of the first embodiment.

FIG. 3 is a schematic cross-sectional view showing a structure of the organic EL apparatus of the first embodiment.

FIG. 4 is a schematic cross-sectional view showing a configuration of a light emitting element in the organic EL apparatus of the first embodiment.

FIG. 5 is a schematic cross-sectional view showing a configuration of a light emitting element of Comparative Example 1.

FIG. 6 is a table showing a configuration of each layer and the evaluation results of the element characteristics in Comparative Examples 1 to 4 and Examples 1 to 7.

FIG. 7 is a schematic cross-sectional view showing a configuration of an organic EL apparatus of the second embodiment.

FIG. 8 is a schematic cross-sectional view showing a configuration of the light emitting element in the organic EL apparatus of the second embodiment.

FIG. 9 is a flowchart showing a method of manufacturing the organic EL apparatus of the second embodiment.

FIGS. 10A to 10E are schematic cross-sectional views showing a method of manufacturing the organic EL apparatus of the second embodiment.

FIGS. 11F to 11J are schematic cross-sectional views showing a method of manufacturing the organic EL apparatus of the second embodiment.

FIG. 12 is a table showing the configuration of each layer and the evaluation results of the element characteristics in the Comparative Example 5 and the Examples 8 to 12 in the second embodiment.

FIG. 13 is a schematic cross-sectional view showing a configuration of the light emitting element in the organic EL apparatus of the third embodiment.

FIG. 14 is a flowchart showing a method of manufacturing the organic EL apparatus of the third embodiment.

FIG. 15 is a table showing a configuration of each layer and the evaluation results of the element characteristics in the Comparative Example 5 and the Examples 13 to 17 in the third embodiment.

FIG. 16 is a schematic cross-sectional view showing a configuration of a light emitting element in an organic EL apparatus of the fourth embodiment.

FIG. 17 is a flowchart showing a method of manufacturing the organic EL apparatus of the fourth embodiment.

FIG. 18 is a table showing the configuration of each layer and the evaluation results of the element characteristics in the Comparative Example 5 and the Examples 18 to 22 in the fourth embodiment.

FIG. 19 is a schematic diagram showing a smartphone as an example of electronic equipment.

### DESCRIPTION OF EXEMPLARY EMBODIMENTS

Hereinafter, specific embodiments of the invention will be described with reference to the drawings. Here, the drawings to be used are displayed after enlarging or reducing as appropriate in order that the portions to be described are recognizable. In addition, the organic EL apparatus may have a top emission structure, or may have a bottom emission structure. In the present embodiment, description will be given of a bottom emission structure as an example.

Here, in the following forms, for example, a case where “on a substrate” is described is set to represent a case where arrangement is performed so as to contact the top of the substrate, a case where arrangement is performed through another constituent component at the top of the substrate, a case where a part is arranged so as to contact the top of the substrate, and a case where a part is arranged through another constituent component.

### First Embodiment

### Configuration of Organic EL Apparatus

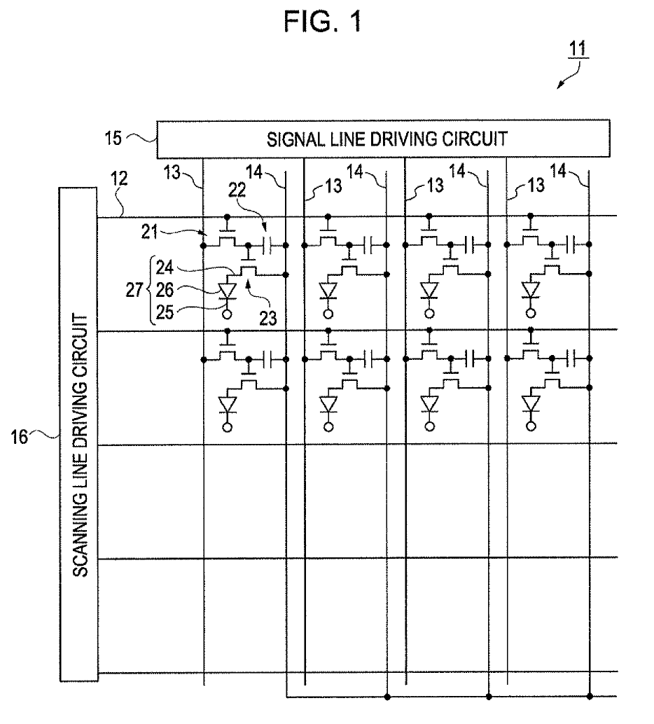

FIG. 1 is an equivalent circuit diagram showing an electrical configuration of the organic EL apparatus of the first embodiment. Below, description will be given of the configuration of the organic EL apparatus of the first embodiment with reference to FIG. 1.

As shown in FIG. 1, an organic EL apparatus 11 of the present embodiment is provided with a plurality of scanning lines 12, a plurality of signal lines 13 extending in a direction intersecting with respect to the scanning lines 12, and a plurality of power lines 14 extending in parallel with the signal lines 13. Then, the region partitioned by the scanning lines 12 and the signal lines 13 is configured as a pixel region. The signal lines 13 are connected to a signal line driving circuit 15. In addition, the scanning lines 12 are connected to a scanning line driving circuit 16.

In each pixel region, there is provided a switching thin film transistor (TFT) 21 supplying a scanning signal to a gate electrode through the scanning lines 12, a storage capacitor 22 storing a pixel signal supplied from the signal lines 13 through the switching TFT 21, and a driving TFT 23 in which the pixel signal stored by the storage capacitor 22 is supplied to the gate electrode. Furthermore, in each pixel region, there is provided an anode 24 in which driving current is made to flow from the power lines 14 when electrically connected to the power lines 14 through the driving TFT 23, a cathode 25, and a functional layer 26 pinched between the anode 24 and the cathode 25.

The organic EL apparatus 11 is provided with a plurality of light emitting elements 27 having the functional layer 26 including a light emitting layer between the anode 24 and the cathode 25. In addition, the organic EL apparatus 11 is provided with a display region configured by a plurality of light emitting elements 27.

According to this configuration, when the scanning lines 12 are driven and the switching TFT 21 enters the on state, the potential of the signal lines 13 at that time is stored in the storage capacitor 22, and the on or off state of the driving TFT 23 is determined according to the potential state stored in the storage capacitor 22. Then, current flows from the power lines 14 to the anode 24 through a channel of the driving TFT 23, further, current flows to the cathode 25 through the functional layer 26. The functional layer 26 emits light at a luminance according to the amount of current flowing through the functional layer 26.

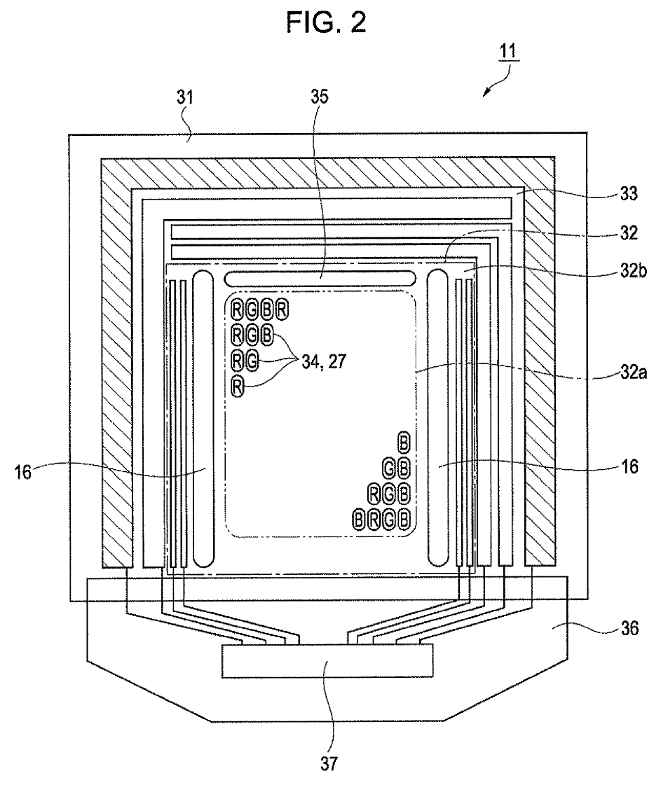

FIG. 2 is a schematic plan view showing a configuration of the organic EL apparatus of the first embodiment. Below, description will be given of the configuration of the organic EL apparatus 11 with reference to FIG. 2.

As shown in FIG. 2, the organic EL apparatus 11 is configured to have a display region 32 (region inside the dashed line in the drawing) and a non-display region 33 (region outside the dashed line) on a substrate 31. The display region 32 is provided with an actual display region 32a (region inside the two-dot chain line) and a dummy region 32b (region outside the two-dot chain line in the drawing).

Inside the actual display region 32a, sub-pixels 34 from which light is irradiated are disposed in a matrix shape. Each of the plurality of sub-pixels 34 is provided with the previously mentioned light emitting elements 27 and is configured to emit light of each color of R (red), G (green), and B (blue) in accordance with the operation of the switching TFT 21 and the driving TFT 23 (refer to FIG. 1).

The dummy region 32b is provided with a circuit mainly for making each sub-pixel 34 emit light. For example, the scanning line driving circuit 16 is arranged along the left side and the right side of the actual display region 32a in the drawing, and a test circuit 35 is arranged along the upper side of the actual display region 32a in the drawing.

The lower side of the substrate 31 in the drawing is provided with a flexible substrate 36. The flexible substrate 36 is provided with a driving IC 37 connected to each wiring.

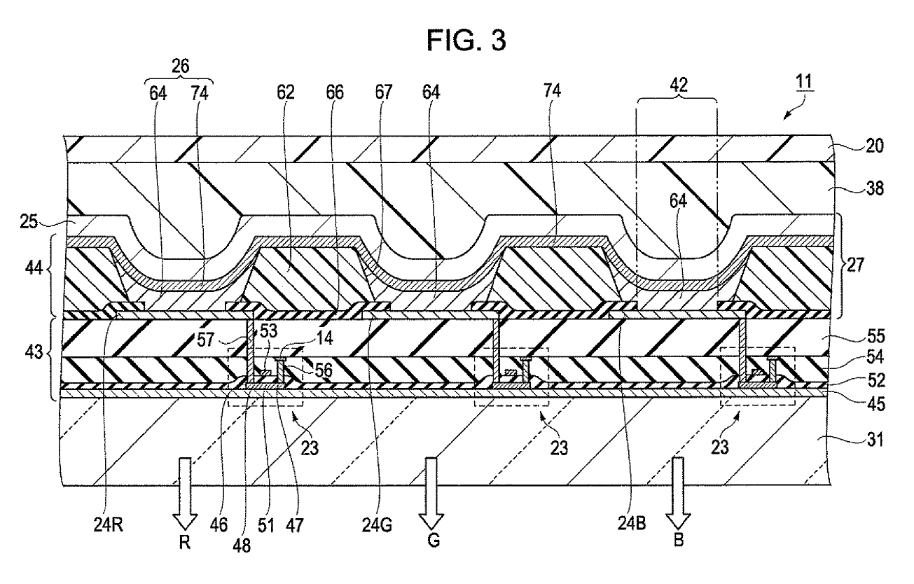

FIG. 3 is a schematic cross-sectional view showing the structure of the organic EL apparatus of the first embodiment. Below, description will be given of the structure of the organic EL apparatus 11 with reference to FIG. 3. FIG. 3 shows the cross-sectional positional relationship of each constituent component, which are represented at a scale which can be understood clearly.

As shown in FIG. 3, the organic EL apparatus 11 performs light emission in a light emitting region 42, and has the substrate 31, a circuit element layer 43 formed on the substrate 31, a light emitting element layer 44 formed on the circuit element layer 43, and a cathode (shared cathode) 25 formed on the light emitting element layer 44. The substrate 31 uses a transparent substrate of glass, plastic, or the like, for example. Here, in a case where the organic EL apparatus 11 is a top emission structure, it is possible for the substrate 31 to use, for example, an opaque substrate of silicon, ceramics, or the like instead of the transparent substrate.

In the circuit element layer 43, a base protective film 45 formed of a silicon oxide film (SiO₂) is formed on the substrate 31, and the driving TFT 23 is formed on the base protective film 45. In detail, an island-shaped semiconductor film 46 formed of a polysilicon film is formed on the base protective film 45. On the semiconductor film 46, a source region 47 and a drain region 48 are formed by the introduction of impurities. Then, the portion into which impurities were not introduced becomes a channel region 51.

Furthermore, in the circuit element layer 43, a transparent gate insulating film 52 formed of a silicon oxide film covering the base protective film 45 and the semiconductor film 46 is formed. On the gate insulating film 52, a gate electrode 53 using a metal material such as aluminum (A1), molybdenum (Mo), tantalum (Ta), titanium (Ti), or tungsten (W), or an alloy or the like of metal materials is formed.

On the gate insulating film 52 and the gate electrode 53, a transparent first interlayer insulating film 54, and a second interlayer insulating film 55 are formed. The first interlayer insulating film 54 and the second interlayer insulating film 55 are, for example, configured of silicon oxide (SiO₂), titanium oxide (TiO₂), or the like. The gate electrode 53 is provided at a position corresponding to the channel region 51 of the semiconductor film 46.

The source region 47 of the semiconductor film 46 of the driving TFT 23 is electrically connected to power lines 14 formed on the first interlayer insulating film 54 through a contact hole 56 provided to pass through the gate insulating film 52 and the first interlayer insulating film 54. On the other hand, the drain region 48 is electrically connected to the anode 24 formed on the second interlayer insulating film 55 through a contact hole 57 provided to pass through the gate insulating film 52, the first interlayer insulating film 54, and the second interlayer insulating film 55.

The anode 24 is formed in each light emitting region 42. In addition, the anode 24 is formed of a transparent Indium Tin Oxide (ITO) film, and has, for example, a shape which is substantially rectangular in plan view. The anodes may be referred to as anodes 24R, 24G, and 24B corresponding to the light emission colors of the sub-pixels 34. The anode 24R corresponds to the first anode in the invention, the anode 24B corresponds to the second anode in the invention, and the anode 24G corresponds to the third anode in the invention.

Here, in the circuit element layer 43, a storage capacitor and a transistor for switching (not shown) are formed. In addition, as described above, in the circuit element layer 43, a transistor for driving (driving TFT 23) connected to each anode 24R, 24G, and 24B is formed.

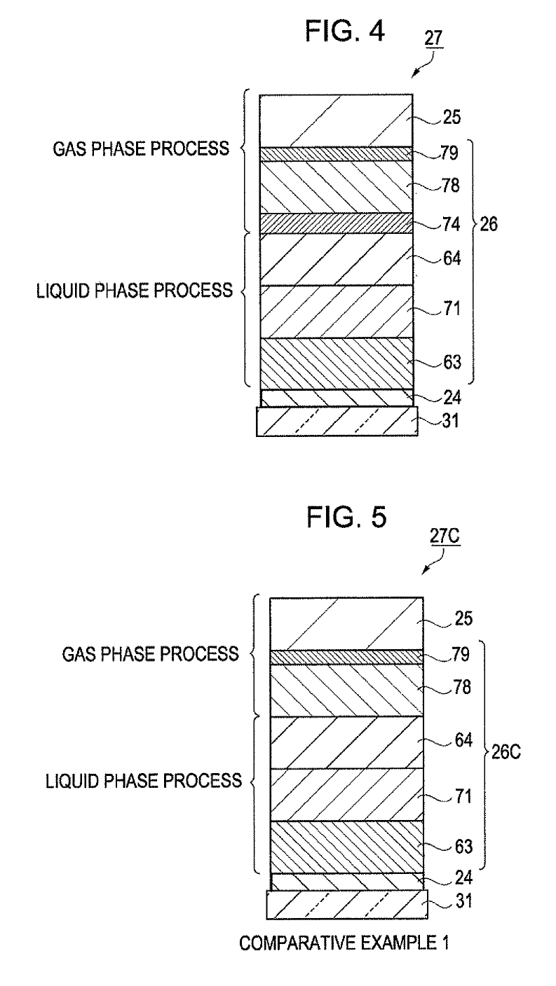

The light emitting element layer 44 is provided with light emitting elements 27 arranged in a matrix shape and is formed on the substrate 31. In detail, the light emitting element layer 44 is mainly configured of the functional layer 26 formed on the anode 24 and a bank (partition wall) 62 partitioning the functional layer 26. For example, the functional layer 26 is configured to include a hole injecting layer 63 (refer to FIG. 4), a light emitting layer 64, an intermediate layer 74 formed in contact with the light emitting layer 64, and the like.

Between the circuit element layer 43 and a bank 62, an insulating layer 66 is formed. Examples of the insulating layer 66 include inorganic materials, such as a silicon oxide film (SiO₂). The insulating layer 66 ensures the insulation property between adjacent anodes 24, and along with this, is formed so as to ride on the peripheral portion of the anodes 24 in order to set the shape of the light emitting region 42 to a desired shape (for example, a track shape). In other words, the anodes 24 and the insulating layer 66 have structures which are arranged so as to partially overlap in plan view. Furthermore, to rephrase, the insulating layer 66 may be formed in a region in which the light emitting region 42 is omitted.

For example, the bank 62 is a trapezoidal shape in which a cross-section has an inclined surface, and is formed to surround the light emitting region 42 (light emitting element 27). In other words, the surrounded region is an opening portion 67 of the bank 62. Examples of the material of the bank 62 include organic materials having heat resistance and solvent resistance such as acrylic resins and polyimide resins.

The hole injecting layer 63 (refer to FIG. 4) is formed of a conductive polymer film containing a dopant in the conductive polymer material. For example, it is possible for such a hole injecting layer to be configured by 3,4-polyethylenedioxythiophene (PEDOT-PSS) containing polystyrene sulfonic acid as a dopant.

Here, although not illustrated in FIG. 3, a hole transporting layer 71 is provided on the hole injecting layer 63 (refer to FIG. 4). The light emitting layer 64 is formed on the hole transporting layer 71 and is a layer of organic light emitting material exhibiting the electroluminescence phenomenon. The intermediate layer 74 is formed on the light emitting layer 64 and an electron transporting layer 78 (refer to FIG. 4) or the like is formed thereon. Over the functional layer 26, on the entirety of the substrate 31 including the top of the bank 62, the cathode 25 is set as a whole surface formed film (solid formed film) in contact with the functional layer 26.

For example, it is possible for the cathode 25 to adopt a configuration in which a lithium fluoride (LiF) layer, a calcium (Ca) layer, and an aluminum (A1) layer, or a configuration in which an alloy such as magnesium silver (MgAg) is used. In addition, other than this, single metals such as lithium, sodium, potassium, rubidium, cesium, magnesium, calcium, strontium, barium, aluminum, copper silver, gold, and the like, or alloys may be used. In addition, cesium carbonate (Cs₂CO₃) may be used.

On the cathode 25, a sealing member 38 made of resin or the like and a sealing substrate 20 are laminated in order to prevent the ingress of water and oxygen. The light emitting element 27 is configured by the anode 24, the functional layer 26, and the cathode 25.

By applying a voltage between the anode 24 and the cathode 25, holes are injected from the anode 24 side and electrons are injected from the cathode 25 side into the light emitting layer 64. In the light emitting layer 64, the energy generated when these carriers (holes and electrons) are bonded is turned to light and emitted.

### Configuration of Light Emitting Element

FIG. 4 is a schematic cross-sectional view showing the configuration of a light emitting element in the organic EL apparatus of the first embodiment. Below, description will be given of the configuration of the light emitting element with reference to FIG. 4.

As shown in FIG. 4, the light emitting element 27 has, in order from the substrate 31, the anode 24, the hole injecting layer 63, the hole transporting layer 71, the light emitting layer 64, the intermediate layer 74, the electron transporting layer 78, an electron injecting layer 79, and the cathode 25.

The substrate 31 is used as a support body of the light emitting element 27. For example, as previously mentioned, the substrate 31 may use glass, plastic, or the like. Here, as long as the substrate functions as the support body of the light emitting element 27, it is not limited to these materials.

Examples of the material of the anode 24 include metal oxides such as ITO, Indium Zinc Oxide (IZO), In₂O₃, SnO₂, fluorine-doped SnO₂, Sb-doped SnO₂, ZnO, Al doped ZnO, and Ga-doped ZnO, Au, Pt, Ag, Cu, or alloys including these, and it is possible to use one kind among these or to combine two or more kinds.

The film thickness of the anode 24 is not particularly limited; however, for example, approximately 10 nm or more to 200 nm or less is preferable, and approximately 30 nm or more to 150 nm or less is more preferable.

Here, in a case where the organic EL apparatus 11 is set as a display panel with a bottom emission structure, since optical transparency is demanded in the anode 24, a metal oxide having optical transparency may be favorably used among the above-described constituent materials.

The hole injecting layer 63 has a function of facilitating the hole injection from the anode 24. As the material of the hole injecting layer 63, in the forming step of the hole injecting layer 63 to be described below, an ion-conducting hole injection material to which an electron-accepting dopant was added to a conductive polymer material (or a conductive oligomer material) may be favorably used in order to achieve the forming using the liquid phase process.

Examples of such an ion-conducting hole injection material include polythiophone based hole injecting material such as poly(3,4-ethylenedioxythiophene)-poly(styrene sulfonic acid) (PEDOT/PSS), polyaniline based hole injection material such as polyaniline-polystyrene sulfonic acid) (PANT/PSS), and oligoaniline based hole injecting material forming a salt with oligoaniline derivatives and an electron-accepting dopant. The film thickness of the hole injecting layer 63 is not particularly limited; however, approximately 5 nm or more to 150 nm or less is preferable and approximately 10 nm or more and 100 nm or less is more preferable.

The hole transporting layer 71 has a function of transporting holes injected from the hole injecting layer 63 up to the light emitting layer 64. In addition, in some cases, the hole transporting layer 71 has a function of blocking electrons entering from the light emitting layer 64 and passing through the hole transporting layer 71.

As the material of the hole transporting layer 71, for example, it is possible to favorably use an amine based compound such as triphenylamine based polymers or the like in order to achieve the forming using the liquid phase process. It is possible to use a polymer organic material based on polysilane or the like including other polyfluorene derivatives (PF) or polyparaphenylenevinylene derivatives (PPV), polyparaphenylene derivatives (PPP), polyvinylcarbazole (PVK), polythiophene derivatives, or poly methyl phenyl silane (PMPS).

The film thickness of the hole transporting layer 71 is not particularly limited; however, approximately 5 nm or more and 100 nm or less is preferable, and approximately 10 nm or more and 50 nm or less is more preferable.

The light emitting layer 64 is configured from a light emitting material. In the configuration of the light emitting layer 64, when a voltage is applied between the anode 24 and the cathode 25, a charge is injected into the light emitting layer 64. In so doing, the holes and electrons are rebonded, excitation energy is generated and the excitation energy moves to the light emitting material, and it is possible to obtain light emission.

The light emitting material configuring the light emitting layer 64 is configured by a host material in which holes and electrons are transported and rebonded, and a dopant which takes in the energy generated from the host material during the rebonding and emits light, or in which the rebonding of the holes and electrons is performed in the dopant itself.

As the host material, there are CBP(4,4′-bis(9-dicarbazolyl)-2,2′-biphenyl), BAlq(bis-(2-methyl-8-quinolinolate)-4-(phenylphenolate) aluminum), mCP(N,N′-dicarbazolyl-3,5-benzene: CBP derivative), CDBP(4,4′-bis(9-carbazolyl)-2,2′-dimethyl-biphenyl), DCB(N,N′-Dicarbazolyl-1,4-dimethene-benzene), P06(2,7-bis(diphenylphosphine oxide)-9,9-dimethylfluorene), SimCP(3,5-bis(9-carbazolyl)tetraphenylsilane), UGH3(W-bis(triphenylsilyl)benzene). These host materials are all low molecular weight organic materials having an electron transporting property. In this embodiment, low molecular weight refers to a molecular weight of less than 1000. In addition, the polymer refers to one having a structure in which the main skeleton is repeated, and the molecular weight is 1000 or more.

As the dopant material, there are phosphorescent materials which emit phosphorescence, and fluorescent materials which emit fluorescence, and, as the phosphorescent materials, there are Ir(ppy)3(Fac-tris(2-phenypyridine)iridium), Ppy2Ir(acac)(Bis(2-phenyl-pyridinato-N,C2)iridium(acetylacetone), Bt2Ir(acac)(Bis(2-phenylbenxothiozolato-N,C2′)iridium(III)(acetylacetonate)), Btp2Ir(acac)(Bis(2-2′-benzothienyl)-pyridinato-N,C3)Iridium(acetylacetonate), FIrpic(Iridium-bis(4,6 difluorophenyl-pyridinato-N,C,2,)-picolinate), Ir(pmb)3(Iridium-tris(1-phenyl-3-methylbenzimidazolin-2-ylidene-C,C(2)′), FIrN4(((Iridium(III)bis(4,6-difluorophenylpyridinato)(5-(pyridin-2-yl)-tetrazolate), Firtaz((Iridium(III)bis(4,6-difluorophenylpyridinato)(5-(pyridine-2-yl)-1,2,4-triazo-late), PtOEP(2,3,7,8,12,13,17,18-Octaethyl-21H,23H-porphine, platinum(II), and the like.

As the fluorescent material, there are Alq3(8-hydroxyquinolinate)aluminum, rubrene, perylene, 9,10-diphenyl anthracene, tetraphenylbutadiene, Nile Red, Coumarin 6, Quinacridone, and the like.

The film thickness of the light emitting layer 64 is not particularly limited; however, approximately 10 nm or more and 150 nm or less is preferable, and approximately 20 nm or more and 100 nm or less is more preferable.

The intermediate layer 74 includes a low molecular weight host material included in the light emitting layer 64 and is formed in contact with the light emitting layer 64. In addition, the intermediate layer 74 is formed using a gas phase process (vapor deposition method).

As the material configuring the intermediate layer 74, for example, there are the above-described CBP(4,4′-bis(9-dicarbazolyl)-2,2′-biphenyl), BAlq(Bis-(2-methyl-8-quinolinolate)-4-(phenylphenolate)aluminum), mCP(N,N-dicarbazolyl-3,5-benzene: CBP derivative), CBP(4,4′-bis(9-carbazolyl)-2,2′-dimethyl-biphenyl), DCB(N,N′-Dicarbazolyl-1,4-dimethene-benzene), P06(2,7-bis(diphenylphosphine oxide)-9,9-dimethylfluorene), SimCP(3,5-bis(9-carbazolyl)tetraphenylsilane), and UGH3(W-bis(triphenylsilyl)benzene). Here, the intermediate layer 74 is configured to include at least one type of the above-described host materials, and may be configured to include a plurality of types.

The thickness of the intermediate layer 74 is preferably approximately 1 nm or more and 5 nm or less. Since the thickness of the intermediate layer 74 is set within the above-described range, it is possible to suppress an increase in the driving voltage or a decrease in the light emitting efficiency caused by placing the intermediate layer 74 between the light emitting layer 64 and the electron transporting layer 78.

The electron transporting layer 78 has a function of transporting injected electrons from the cathode 25 to the intermediate layer 74 and the light emitting layer 64.

The material of the electron transporting layer 78 (electron transporting material) is not particularly limited; however, in the forming step of the electron transporting layer to be described below, in order to achieve the forming using the gas phase process, for example, oxadiazole derivatives such as BAlq, OXD-1,1,3,5-tri(5-(4-tert-butylphenyl)-1,3,4-oxadiazole), BCP(Bathocuproine), PBD(2-(4-biphenyl)-5-(4-tert-butylphenyl)-1,2,4-oxadiazole), tBu-PBD(2-(4-tert-butylphenyl)-5-(4-biphenyl)-1,3,4-oxadiazole), DPVBi(4,4′-bis(1,1-diphenylethenyl)biphenyl), BND(2,5-bis(1-naphthyl)-1,3,4-oxadiazole), DTVBi(4,4′-bis(1,1-bis(4-methylphenyl)ethenyl)biphenyl), BBD (2,5-bis(4-biphenylyl)-1,3,4-oxadiazole), oxazole derivatives, triazole derivatives such as TAZ(3-(4-biphenyl)-4-phenyl-5-(4-tert-butylphenyl)-1,2,4-triazole), fenansororin derivatives, anthraquinodimethane derivatives, benzoquinone derivatives, naphthoquinone derivatives, anthraquinone derivatives, tetracyanoanthraquinodimethane derivatives, fluorenone derivatives, diphenyldicyanoethylene derivative, diphenoquinone derivatives, quinoline derivatives such as organic metal complexes with hydroxyquinoline derivatives or derivatives thereof set as ligands, silole derivatives, pyridine derivatives, pyrimidine derivatives, quinoxaline derivative containing nitrogen heterocyclic derivatives, and the like may be favorably used, and it is possible to use one kind among these or to combine two or more kinds.

The film thickness of the electron transporting layer 78 is not particularly limited; however, approximately 1 nm or more and 100 nm or less is preferable, and approximately 5 nm or more and 50 nm or less is more preferable. In this manner, it is possible to favorably transport electrons injected into the electron transporting layer 78 to the light emitting layer 64.

The electron injecting layer 79 has a function of improving the injection efficiency of electrons from the cathode 25 to the electron transporting layer 78. The electron injecting material configuring the electron injecting layer 79 is not particularly limited; however, in order to achieve the forming using the gas phase process such as the vapor deposition method, possible examples include alkali metal compound and alkaline earth metal compounds.

Examples of the alkali metal compounds include alkali metal salts such as LiF, Li₂CO₃, LiCl, NaF, Na₂CO₃, NaCl, CsF, Cs₂CO₃, CsCl, and the like. In addition, examples of the alkaline earth metal compounds include alkaline earth metal salts such as CaF₂, CaCO₃, SrF₂, SrCO₃, BaF₂, BaCO₃, and the like. It is possible to use one kind among these alkali metal compounds and alkaline earth metal compound or to combine two or more kinds.

The film thickness of the electron injecting layer 79 is not particularly limited; however, approximately 0.01 nm or more and 100 nm or less is preferable, and approximately 0.1 nm or more and 10 nm or less is more preferable. Here, it is possible to omit the electron injecting layer 79 according to the combination of the types of constituent material of the electron transporting layer 78 and the cathode 25, the film thicknesses thereof, and the like.

The cathode 25 is an electrode injecting electrons into the electron transporting layer 78 through the electron injecting layer 79. As the material of the cathode 25, it is preferable to use a material with a low work function, and in order to achieve the forming using the gas phase process in the forming step of the cathode 25 to be described later, for example, Li, Mg, Ca, Sr, La, Ce, Er, Eu, Sc, Y, Yb, Ag, Cu, Al, Cs, Rb, Au, alloys including the above, or the like, may be used, and it is possible to use one type or a combination (for example, laminate body having a plurality of layers, or the like) of two or more types from the above.

In addition, for the cathode 25, it is desirable to use a metal, an alloy, an electrically conductive compound, a mixture of these, or the like with a work function smaller than that the anode 24. For example, there are elements belonging to Group 1 or Group 2 of the Periodic Table of the Elements, that is, alkali metals, such as lithium and cesium, alkaline earth metals such as magnesium, calcium, strontium, and the like, MgAg, ALLi, Europium, ytterbium, and the like, which are alloys including these.

In particular, in the present embodiment, in a case of the organic EL apparatus 11 with a bottom emission structure, optical transparency is not required in the cathode 25, and, as the constituent material of the cathode 25, for example, metals or alloys such as Al, Ag, AlAg, and AlNd may be preferably used. By using the above metals and alloys as the constituent material of the cathode 25, it is possible to achieve an increase in the electron injection efficiency and stability properties of the cathode 25.

The film thickness of the cathode 25 in the bottom emission structure is not particularly limited; however, approximately 50 nm or more and 1000 nm or less is preferable, and approximately 100 nm or more and 500 nm or less is more preferable.

Here, in a case where the organic EL apparatus 11 has a top emission structure, alloys such as MgAg, MgAl, MgAu, and AlAg are preferably used as the constituent material of the cathode 25. By using the above metals and alloys as the constituent material of the cathode 25, it is possible to achieve an increase in the electron injection efficiency and stability properties of the cathode 25 while maintaining the optical transparency of the cathode 25.

The film thickness of the cathode 25 in the top emission structure is not particularly limited; however, approximately 1 nm or more and 50 nm or less is preferable, and approximately 5 nm or more and 20 nm or less is more preferable. Below, description will be given of the method of manufacturing the light emitting element 27.

### Method of Manufacturing Light Emitting Element

### Hole Injection Layer Forming Step

In the hole injecting layer forming step, first, a hole injecting layer forming ink is coated using an ink jet method. Specifically, a hole injecting layer forming ink (liquid material) containing hole injecting material is discharged from the head of the ink jet printing apparatus and coated on the anode 24.

Here, examples of the solvents (ink solvents) or dispersion media (ink dispersion media) used in the preparation of the hole injecting layer forming ink include various inorganic solvents such as nitric acid, sulfuric acid, ammonia, hydrogen peroxide, water, carbon disulfide, carbon tetrachloride, and ethylene carbonate; ketone based solvents such as methyl ethyl ketone (MEK), acetone, diethyl ketone, methyl isobutyl ketone (MIBK), methyl isopropyl ketone (MIPK), and cyclohexanone; alcohol based solvents such as methanol, ethanol, isopropanol, ethylene glycol, diethylene glycol (DEG), and glycerine; ether based solvents such as diethyl ether, diisopropyl ether, 1,2-dimethoxyethane (DME), 1,4-dioxane, tetrahydrofuran (THF), tetrahydropyran (THP), anisole, diethylene glycol dimethyl ether (diglyme), and diethylene glycol ethyl ether (carbitol); cellosolve-based solvents such as methyl cellosolve, ethyl cellosolve, and phenyl cellosolve; aliphatic hydrocarbon based solvents such as hexane, pentane, heptane, and cyclohexane; alicyclic hydrocarbon based solvents such as cyclohexane, and tetralin; aromatic hydrocarbon based solvents such as toluene, xylene, benzene, trimethylbenzene, tetramethylbenzene, and 3-phenoxytoluene; aromatic heterocyclic compound based solvents such as pyridine, pyrazine, furan, pyrrole, thiophene, and methyl pyrrolidone; amide based solvents such as N,N-dimethyl formamide (DMF), and N,N-dimethylacetamide (DMA); halogen compound based solvents such as dichloromethane, chloroform, 1,2-dichloroethane; ester solvents such as ethyl acetate, methyl acetate, and ethyl formate; sulfur compound based solvents such as dimethyl sulfoxide (DMSO), and sulfolane; nitrile based solvents such as acetonitrile, propionitrile, and acrylonitrile; various types of organic solvents such as organic acid based solvents such as formic acid, acetic acid, trichloroacetic acid, and trifluoroacetic acid; a mixed solvent including the above, or the like.

Here, the hole injecting layer forming ink (liquid material) coated on the anode 24 has high fluidity (low viscosity) and tries to spread in the horizontal direction (surface direction); however, since the anode 24 is surrounded by the bank 62, spreading outside a predetermined region is prevented, and the contour shape of the hole injecting layer 63 is defined precisely.

Next, post processing is performed with respect to the coated hole injecting layer forming ink. Specifically, the hole injecting layer forming ink coated on the anode 24 is dried and the hole injecting layer 63 is formed. By this drying, it is possible to remove the solvent or the dispersion medium. Examples of methods of drying include a method of being left to stand in a reduced-pressure atmosphere, a method using a heating process (for example, approximately 40° C. or more and 80° C. or less), a method using the flow of an inert gas such as nitrogen gas, and the like. Furthermore, according to necessity, the substrate 31 in which the hole injecting layer 63 is formed is heated (baked) at approximately 100° C. or more and 300° C. or less. By this heating, it is possible to remove the solvent or dispersion medium remaining in the film of the hole injecting layer 63 after drying.

In addition, in a case where a hole injection material which is cross-linked by heating and made insoluble with respect to the solvent is used, it is also possible to make the hole injecting layer 63 insoluble by the heating. In addition, after this heating, in order to remove the non-insoluble portion of the hole injecting layer 63, the surface of the substrate 31 in which the hole injecting layer 63 is formed may be rinsed (cleaned) using a solvent. By this rinsing, it is possible to prevent the non-insoluble portion of the hole injecting layer 63 from mixing with the hole transporting layer 71 formed on top of the hole injecting layer 63.

### Hole Transporting Layer Forming Step

In the hole transporting layer forming step, first, hole transporting layer forming ink is coated on the hole injecting layer 63 using an ink jet method in the same manner as the hole injecting layer forming step, and then post processing similar to the hole injecting layer forming step is performed with respect to the coated hole transporting layer forming ink. However, the ink solvent or dispersion medium used in the hole transporting layer forming ink, the post processing method and conditions, and the like are appropriately selected as suitable for the forming of the hole transporting layer 71.

Here, examples of the solvents (ink solvents) or dispersion media (ink dispersion media) used in the preparation of the hole transporting layer forming ink include various inorganic solvents such as nitric acid, sulfuric acid, ammonia, hydrogen peroxide, water, carbon disulfide, carbon tetrachloride, and ethylene carbonate; ketone based solvents such as methyl ethyl ketone (MEK), acetone, diethyl ketone, methyl isobutyl ketone (MIBK), methyl isopropyl ketone (MIPK), and cyclohexanone; alcohol based solvents such as methanol, ethanol, isopropanol, ethylene glycol, diethylene glycol (DEG), and glycerine; ether based solvents such as diethyl ether, diisopropyl ether, 1,2-dimethoxyethane (DME), 1,4-dioxane, tetrahydrofuran (THF), tetrahydropyran (THP), anisole, diethylene glycol dimethyl ether (diglyme), and diethylene glycol ethyl ether (carbitol); cellosolve-based solvents such as methyl cellosolve, ethyl cellosolve, and phenyl cellosolve; aliphatic hydrocarbon based solvents such as hexane, pentane, heptane, and cyclohexane; alicyclic hydrocarbon based solvents such as cyclohexane, and tetralin; aromatic hydrocarbon based solvents such as toluene, xylene, benzene, trimethylbenzene, tetramethylbenzene, and 3-phenoxytoluene; aromatic heterocyclic compound based solvents such as pyridine, pyrazine, furan, pyrrole, thiophene, and methylpyrrolidone; amide based solvents such as N,N-dimethyl formamide (DMF), and N,N-dimethylacetamide (DMA); halogen compound based solvents such as dichloromethane, chloroform, 1,2-dichloroethane; ester solvents such as ethyl acetate, methyl acetate, and ethyl formate; sulfur compound based solvents such as dimethyl sulfoxide (DMSO), and sulfolane; nitrile based solvents such as acetonitrile, propionitrile, and acrylonitrile; various types of organic solvents such as organic acid based solvents such as formic acid, acetic acid, trichloroacetic acid, and trifluoroacetic acid; a mixed solvent including the above, or the like.

### Light Emitting Layer Forming Step

In the light emitting layer forming step, first, light emitting layer forming ink is coated on the hole transporting layer 71 using an ink jet method, and then post processing similar to the hole injecting layer forming step is performed with respect to the coated light emitting layer forming ink. However, the ink solvent or ink dispersion medium used in the light emitting layer forming ink, the post processing method and conditions, and the like are appropriately selected as suitable for the forming of the light emitting layer 64.

Here, examples of the solvents (ink solvents) or dispersion media (ink dispersion media) used in the preparation of the light emitting layer forming ink include various inorganic solvents such as nitric acid, sulfuric acid, ammonia, hydrogen peroxide, water, carbon disulfide, carbon tetrachloride, and ethylene carbonate; ketone based solvents such as methyl ethyl ketone (MEK), acetone, diethyl ketone, methyl isobutyl ketone (MIBK), methyl isopropyl ketone (MIPK), and cyclohexanone; alcohol based solvents such as methanol, ethanol, isopropanol, ethylene glycol, diethylene glycol (DEG), and glycerine; ether based solvents such as diethyl ether, diisopropyl ether, 1,2-dimethoxyethane (DME), 1,4-dioxane, tetrahydropyran (THF), tetrahydropyran (THP), anisole, diethylene glycol dimethyl ether (diglyme), and diethylene glycol ethyl ether (carbitol); cellosolve-based solvents such as methyl cellosolve, ethyl cellosolve, and phenyl cellosolve; aliphatic hydrocarbon based solvents such as hexane, pentane, heptane, and cyclohexane; alicyclic hydrocarbon based solvents such as cyclohexane, and tetralin; aromatic hydrocarbon based solvents such as toluene, xylene, benzene, trimethylbenzene, tetramethylbenzene, and 3-phenoxytoluene; aromatic heterocyclic compound based solvents such as pyridine, pyrazine, furan, pyrrole, thiophene, and methyl pyrrolidone; amide based solvents such as N,N-dimethyl formamide (DMF), and N,N-dimethylacetamide (DMA); halogen compound based solvents such as dichloromethane, chloroform, 1,2-dichloroethane; ester solvents such as ethyl acetate, methyl acetate, and ethyl formate; sulfur compound based solvents such as dimethyl sulfoxide (DMSO), and sulfolane; nitrile based solvents such as acetonitrile, propionitrile, and acrylonitrile; various types of organic solvents such as organic acid based solvents such as formic acid, acetic acid, trichloroacetic acid, and trifluoroacetic acid; a mixed solvent including the above, or the like.

In the above hole injecting layer forming step, hole transporting layer forming step, and light emitting layer forming step, it is preferable to use an ink jet method. In the ink jet method, since it is possible to control with high precision the discharge amount of the ink and the landing position of the ink droplets regardless of the size of the area of the substrate 31, by using such a method, it is possible to achieve the miniaturization of the pixel size, as well as to increase the area of the organic EL apparatus 11.

In addition, without being limited to the ink jet method, in the hole injecting layer forming step, the hole transporting layer forming step, and the light emitting layer forming step, it is possible to use a liquid phase process such as a spin coating method (pyrosol process), a casting method, a micro gravure coating method, a gravure coating method, a bar coating method, a roll coating method, a wire bar coating method, a dip coating method, a spray coating method, a screen printing method, a flexographic printing method, an offset printing method, or the like.

### Intermediate Layer Forming Step

In the intermediate layer forming step, the intermediate layer 74 including a low molecular weight host material included in the light emitting layer 64 is formed in contact with the light emitting layer 64. Examples of the method of forming the intermediate layer 74 include the gas phase process such as the vapor deposition method. The post processing method and conditions, and the like are appropriately selected as suitable for the forming of the intermediate layer 74.

### Electron Transporting Layer Forming Step

In the electron transporting layer forming step, the electron transporting layer 78 is formed using the gas phase process such as the vapor deposition method so as to cover the intermediate layer 74. In this manner, the electron transporting layer 78 is formed in common over each light emitting element 27.

### Electron Injecting Layer Forming Step

In the electron injecting layer forming step, the electron injecting layer 79 is formed using the gas phase process such as the vapor deposition method so as to cover the electron transporting layer 78. In this manner, the electron injecting layer 79 is formed in common over each light emitting element 27.

### Cathode Forming Step

In the cathode forming step, the cathode 25 is formed using the gas phase process such as the vapor deposition method so as to cover the electron injecting layer 79. In this manner, the cathode 25 is formed in common over each light emitting element 27. Through the above steps, the organic EL apparatus 11 is completed.

In the above-described light emitting elements 27, by performing film formation using the liquid phase process such as the ink jet method up to the light emitting layer 64 in the functional layer 26, it is possible to easily separate the coating of the light emitting layers 64 having different light emission colors and to easily realize an increase in the area of the organic EL apparatus 11.

In addition, in the above-described light emitting elements 27, by forming the film of the upper layer from the light emitting layer 64 using a gas phase process, each light emitting element 27 is provided with a sufficient light emission lifetime at a practical level.

In addition, by arranging the intermediate layer 74 formed of a vapor deposited film including a low molecular weight host material included in the light emitting layer 64 in the gas phase process between the light emitting layer 64 formed by the liquid phase process and the electron transporting layer 78 formed by the gas phase process, it is possible to smoothly perform transporting of the electrons from the cathode 25 to the light emitting layer 64. Thus, it is possible to suppress the generation of dark spots and the reduction of the light emitting area and it is possible to improve the display characteristics.

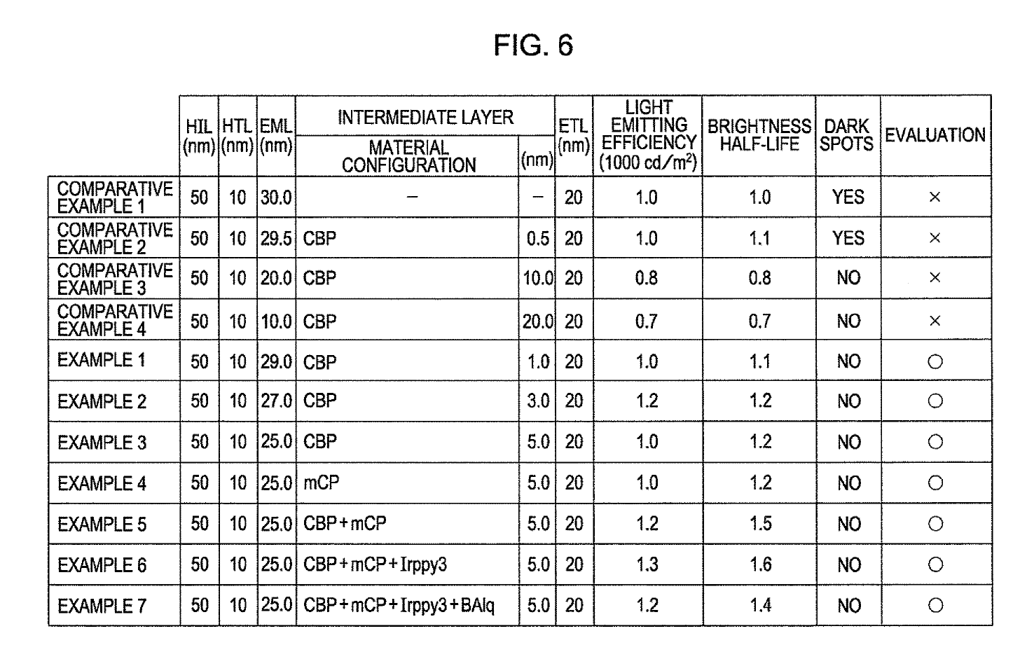

Next, description will be given with reference to FIG. 5 and FIG. 6 showing specific Comparative Examples 1 to 4 and Examples 1 to 7. FIG. 5 is a schematic cross-sectional view showing a configuration of a light emitting element of Comparative Example 1. FIG. 6 is a table showing the configuration of each layer and the evaluation results of the element characteristics in the Comparative Examples 1 to 4 and the Examples 1 to 7. Here, the same reference numerals will be given to Comparative Examples 1 to 4 as in Example 1 and the detailed description thereof will be omitted. In the table of FIG. 6, HIL indicates the hole injecting layer, HTL indicates the hole transporting layer, EML indicates the light emitting layer, and ETL indicates the electron transporting layer. In addition, since the configuration of the electron injecting layer is the same in Comparative Examples 1 to 4 and Examples 1 to 7, description thereof is omitted in the table.

### Comparative Example 1

As shown in FIG. 5, in a light emitting element 27C of Comparative Example 1, the hole injecting layer 63, the hole transporting layer 71, and the light emitting layer 64 are formed by the liquid phase process on the anode 24 of the substrate 31. Thereafter, the electron transporting layer 78, the electron injecting layer 79, and the cathode 25 are formed by the gas phase process. In other words, a functional layer 26C of the light emitting element 27C is configured not to include the intermediate layer 74 between the light emitting layer 64 and the electron transporting layer 78.

As shown in FIG. 6, the film thicknesses of each layer are 50 nm for the hole injecting layer 63, 10 nm for the hole transporting layer 71, 30 nm for the light emitting layer 64, 20 nm for the electron transporting layer 78, and 200 nm for the cathode 25. The details of the materials and the like are the same as the configuration of the light emitting element 27 of the above-described embodiment with the exception of the intermediate layer 74.

Specifically, first, a transparent glass substrate with a thickness of 1.0 mm was prepared as the substrate 31. Next, after an ITO film with a thickness of 50 nm was formed on the substrate 31 using the sputtering method, the anode 24 is formed by patterning this ITO film using a photolithography method. Then, after the substrate 31 in which the anode 24 is formed was immersed in acetone and 2-propanol in order and subjected to ultrasonic cleaning, an oxygen plasma treatment was performed.

Next, after an insulating film configured by an acrylic based resin was formed using a spin coating method on the substrate 31 in which the anode 24 was formed, the bank 62 was formed by patterning this insulating layer using the photolithography method such that the anode 24 is exposed. Furthermore, the surface of the substrate 31 in which the bank 62 was formed is first subjected to a plasma treatment using O₂ gas as the treatment gas. In this manner, the surface of the anode 24 and the surface of the bank 62 (including the wall surfaces) are activated and lyophilized. Subsequently, the surface of the substrate 31 in which the bank 62 was formed is subjected to a plasma treatment using CF₄ gas as the treatment gas. In this manner, the CF₄ gas reacts with and makes lyophobic only the surface of the bank 62 formed of the acrylic based resin.

Next, at the inner side of the bank 62 positioned in the region in which the light emitting element 27 is to be formed, a 1.0 wt % PEDOT/PSS aqueous dispersion medium which is a hole injecting layer forming ink is coated using the ink jet method.

Next, after drying the PEDOT/PSS aqueous dispersion medium coated in each of the above-described steps, the substrate 31 was heated in the atmosphere, and an ion conductive hole injecting layer 63 with a film thickness of 50 nm configured of PEDOT/PSS was formed.

Next, at the inner side of the bank 62 positioned in the region in which the light emitting layer 64 is to be formed, a triphenylamine based polymer 1.5 wt % tetramethyl benzene solution which is a hole transporting layer forming ink is coated using the ink jet method.

Next, after drying the tetramethyl benzene solution of triphenylamine based polymer coated in each of the above-described steps, the substrate 31 was heated in a nitrogen atmosphere. Furthermore, the region of the substrate 31 in which the light emitting layer 64 is to be formed was rinsed with xylene. In this manner, on each hole injecting layer 63, hole transporting layers 71 with a film thickness of 10 nm configured by the triphenylamine based polymer were formed respectively.

Next, at the inner side of the bank 62 positioned in the region in which the light emitting layer 64 is to be formed, a tetramethyl benzene solution, which is a light emitting layer forming ink including 1.2 wt % of CBP and mCP as the host material and three types of dopant Irppy3, is coated using the ink jet method.

Next, after drying the coated light emitting layer forming ink, the substrate 31 is heated in a nitrogen atmosphere. In this manner, on each hole transporting layer 71, light emitting layers 64 with a film thickness of 30 nm configured by the host material CBP, mCP, and dopant Irppy3 were formed respectively.

Next, on the light emitting layer 64, the electron transporting layer 78 with a film thickness of 20 nm configured by tris-(8-quinolinolato)aluminum (Alq3) is formed using the vapor deposition method.

Next, on the electron transporting layer 78, the electron injecting layer 79 with a film thickness of 1 nm configured by lithium fluoride (LiF) is formed using the vapor deposition method.

Next, on the electron injecting layer 79, the cathode 25 with a film thickness of 200 nm configured by Al is formed using the vapor deposition method.

Next, a protective cover (sealing member) made of glass is overlaid so as to cover each layer, fixed using epoxy resin, and sealed. According to the above steps, the organic EL apparatus having the light emitting element 27C with the bottom emission structure as shown in FIG. 5 is manufactured.

### Comparative Example 2

As shown in FIG. 6, with respect to Comparative Example 1, in Comparative Example 2, the film thickness of the light emitting layer 64 is set to 29.5 nm and the intermediate layer 74 is configured between the light emitting layer 64, which is a coated film, and the electron transporting layer 78, which is a vapor deposited film, by forming the CBP which is the host material included in the light emitting layer 64 so as to have a film thickness of 0.5 nm by the vapor deposition method.

### Comparative Example 3

As shown in FIG. 6, with respect to Comparative Example 1, in Comparative Example 3, the film thickness of the light emitting layer 64 is set to 20.0 nm and the intermediate layer 74 is configured between the light emitting layer 64, which is a coated film, and the electron transporting layer 78, which is a vapor deposited film, by forming the CBP which is the host material included in the light emitting layer 64 so as to have a film thickness of 10.0 nm by the vapor deposition method.

### Comparative Example 4

As shown in FIG. 6, with respect to Comparative Example 1, in Comparative Example 4, the film thickness of the light emitting layer 64 is set to 10.0 nm and the intermediate layer 74 is configured between the light emitting layer 64, which is a coated film, and the electron transporting layer 78, which is a vapor deposited film, by forming the CBP which is the host material included in the light emitting layer 64 so as to have a film thickness of 20.0 nm by the vapor deposition method.

### Example 1

As shown in FIG. 6, in the light emitting element 27 of Example 1, the hole injecting layer 63, the hole transporting layer 71, and the light emitting layer 64 are formed by the liquid phase process on the anode 24. Thereafter, the intermediate layer 74, the electron transporting layer 78, the electron injecting layer 79, and the cathode 25 are formed by the gas phase process. In other words, with respect to Comparative Example 1, between the light emitting layer 64, which is a coated film, and the electron transporting layer 78, which is a vapor deposited film, the intermediate layer 74, which is a vapor deposited film, is added.

Specifically, on the hole transporting layers 71, light emitting layers 64 with a film thickness of 29 nm configured by the host material CBP, mCP, and dopant Irppy3 were formed respectively by the liquid phase process (ink jet method).

Next, the intermediate layer 74 is formed on the light emitting layer 64 using the vapor deposition method with the film thickness of the host material CBP included in the light emitting layer 64 as 1 nm. The total film thickness of the light emitting layer 64 and the intermediate layer 74 is 30 nm.

Next, on the intermediate layer 74, the electron transporting layer 78 with a film thickness of 20 nm configured by tris-(8-quinolinolato) aluminum(Alq3) is formed using the vapor deposition method.

Next, on the electron transporting layer 78, the electron injecting layer 79 with a film thickness of 1 nm configured by lithium fluoride (LiF) is formed using the vapor deposition method.

Next, on the electron injecting layer 79, the cathode 25 with a film thickness of 200 nm configured by Al is formed using the vapor deposition method.

Next, a protective cover (sealing member) made of glass is overlaid so as to cover each layer, fixed using epoxy resin, and sealed. According to the above steps, the organic EL apparatus 11 having the light emitting element 27 with the bottom emission structure as shown in FIG. 4 is manufactured.

### Example 2

With respect to Example 1, in Example 2, the film thickness of the light emitting layer 64 is set to 27.0 nm and the film thickness of the intermediate layer 74 is set to 3.0 nm. That is, the total film thickness of the light emitting layer 64 and the intermediate layer 74 is 30 nm, which is the same as Example 1.

### Example 3

With respect to Example 1, in Example 3, the film thickness of the light emitting layer 64 is set to 25.0 nm and the film thickness of the intermediate layer 74 is set to 5.0 nm. That is, the total film thickness of the light emitting layer 64 and the intermediate layer 74 is 30 nm, which is the same as Example 1.

### Example 4

With respect to Example 1, in Example 4, the film thickness of the light emitting layer 64 is set to 25.0 nm and the intermediate layer 74 is configured using mCP, which is the host material, and the film thickness thereof is set to 5.0 nm. That is, the total film thickness of the light emitting layer 64 and the intermediate layer 74 is 30 nm, which is the same as Example 1.

### Example 5

With respect to Example 1, in Example 5, the film thickness of the light emitting layer 64 is set to 25.0 nm and the intermediate layer 74 is configured using two types of host material, CBP and mCP, and the film thickness thereof is set to 5.0 nm. That is, the total film thickness of the light emitting layer 64 and the intermediate layer 74 is 30 nm, which is the same as Example 1.

### Example 6

With respect to Example 1, in Example 6, the film thickness of the light emitting layer 64 is set to 25.0 nm and the intermediate layer 74 is configured by further adding Irppy3, which is a dopant, to two types of host material, CBP and mCP, and the film thickness thereof is set to 5.0 nm. That is, the intermediate layer 74 which has the same material configuration as the light emitting layer 64 is formed on the light emitting layer 64, which is a coating layer, by the vapor deposition method, and the total film thickness of the light emitting layer 64 and the intermediate layer 74 is 30 nm, which is the same as Example 1.

### Example 7

With respect to Example 1, in Example 7, the film thickness of the light emitting layer 64 is set to 25.0 nm and the intermediate layer 74 is configured by further adding BAlq, which is an electron transporting material to the two types of host material, CBP and mCP, and the Irppy3, which is a dopant, and the film thickness thereof is set to 5.0 nm. The total film thickness of the light emitting layer 64 and the intermediate layer 74 is 30 nm, which is the same as Example 1.

The evaluation of the element characteristics of Comparative Examples 1 to 4 and Examples 1 to 7 was determined according to three items of light emitting efficiency, brightness half-life, and dark spots. The light emitting efficiency is quantified on the basis of Comparative Example 1 based on the current amount when the brightness is 1000 cd/m². The brightness half-life is quantified on the basis of Comparative Example 1 based on the energization time when the brightness is 500 cd/m², which is half of 1000 cd/m². The dark spots are set on the basis of the presence or absence of the generation thereof at the time point when the brightness was reduced by half. The evaluation takes these three items together and indicates one of “X”, not at a level for practical use, “◯”, at a level for practical use, and “⊙”, exceeds a level for practical use.

As shown in FIG. 6, the organic EL apparatuses of Comparative Example 1 and Comparative Example 2 are similar in light emitting efficiency and brightness half-life; however, the evaluation is “X” as dark spots were observed after the half-life.

The organic EL apparatuses 11 of Example 1 to Example 3 are equal to or more than the Comparative Example 1 in light emitting efficiency and brightness half-life, and the evaluation is “◯” as dark spots were not observed after the half-life. In particular, Example 2, in which the film thickness of the intermediate layer 74 was 3 nm, was superior to Comparative Example 1 and Comparative Example 2 in both the light emitting efficiency and brightness half-life.

In Comparative Example 3 and Comparative Example 4, in which the film thickness of the intermediate layer 74 was set to 10 nm or more, the generation of dark spots was not seen; however, since decreases in the light emitting efficiency and the brightness half-life as a result of pinching the intermediate layer 74 between the light emitting layer 64 and the electron transporting layer 78 were seen, the evaluation is “X”.

Even when mCP was used for the host material configuring the intermediate layer 74 as in Example 4 without being limited to CSP, it is possible to obtain the effect of pinching the intermediate layer 74, which is a vapor deposited film, between the light emitting layer 64, which is a coated film, and the electron transporting layer 78, which is a vapor deposited film. In addition, without limiting the host material configuring the intermediate layer 74 to one type, the effect thereof is exhibited even when a dopant such as Irppy3 or an electron transporting material such as BAlq are included, as well as the plurality of types of host material as in Example 5 to Example 7. Accordingly, the evaluation of Example 4 to Example 7 is “◯”.

Among the above, the configuration of the organic EL apparatus of Example 6 is considered preferable from the point of being able to obtain the most superior light emitting efficiency (1.3 times) and the light emitting lifetime (1.6 times) with respect to Comparative Example 1.

The effects of the first embodiment described above are as follows.

(1) According to the organic EL apparatus 11 and the method of manufacturing thereof of the above-described first embodiment, between the light emitting layer 64 which is a coated film and the cathode 25 (specifically, the electron transporting layer 78) which is a vapor deposited film, since the intermediate layer 74 including a low molecular weight host material included in the light emitting layer 64 is formed in contact with the light emitting layer 64 using the gas phase process (vapor deposition method), it is possible to smoothly perform transportation of electrons from the cathode 25 to the light emitting layer 64. Thus, it is possible to suppress the generation of dark spots and the reduction of the light emitting area and it is possible to provide or manufacture the organic EL apparatus 11 provided with the light emitting element 27 having an excellent light emitting efficiency and light emitting lifetime.

(2) In addition, since the total film thicknesses of the intermediate layer 74 and the light emitting layer 64 are set in a provided with range (for example, to 30 nm) determined according to the light emitting wavelength, it is possible to improve the light emitting efficiency and, along with this, it is possible to display predetermined colors. Here, the light emitting efficiency indicates the current efficiency or the external quantum efficiency. In addition, since the thickness of the intermediate layer 74 is set to 1 nm or more and 5 nm or less, it is possible to suppress an increase in the driving voltage or a decrease in the light emitting efficiency caused by forming the intermediate layer 74 between the light emitting layer 64 and the electron transporting layer 78.

### Second Embodiment

### Configuration of Organic EL Apparatus

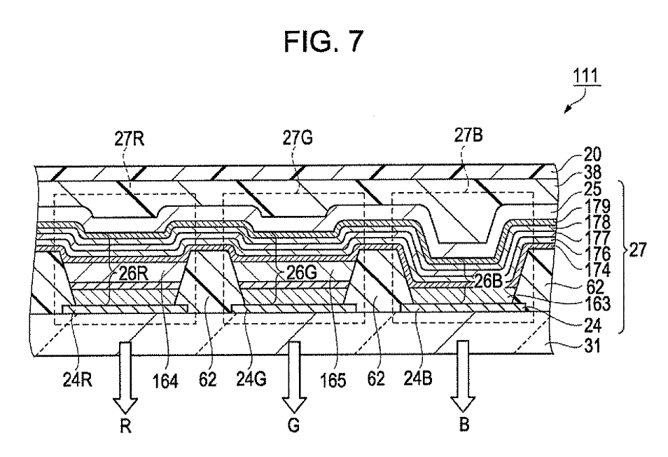

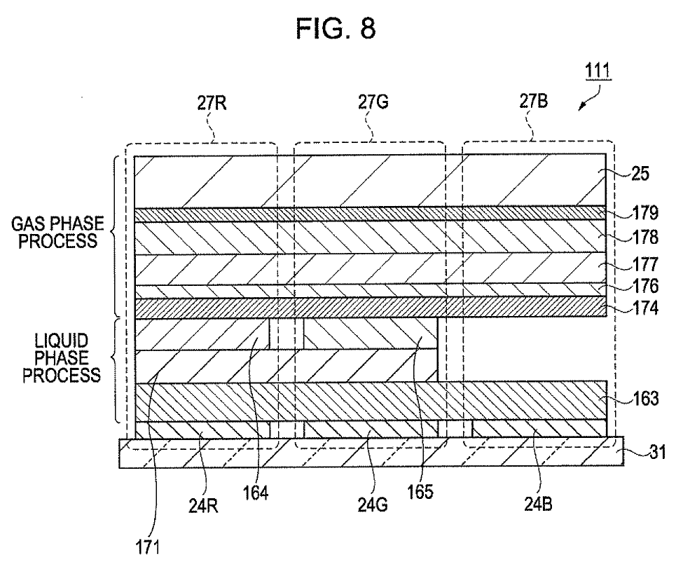

Next, description will be given of the organic EL apparatus of the second embodiment with reference to FIG. 7 and FIG. 8. FIG. 7 is a schematic cross-sectional view showing the configuration of the organic EL apparatus of the second embodiment and FIG. 8 is a schematic cross-sectional view showing the configuration of the light emitting element in the organic EL apparatus of the second embodiment. With respect to the organic EL apparatus 11 of the first embodiment, in the organic EL apparatus of the second embodiment, the configuration of each of the red (R), green (G), and blue (B) light emitting elements is different. Here, where the configuration is the same as the first embodiment, the same reference numerals will be given and the detailed description thereof will be omitted.

As shown in FIG. 7, an organic EL apparatus 111 of the present embodiment has the substrate 31 provided with a light emitting element 27R (equivalent to the first light emitting element according to an aspect of the invention) provided corresponding to the red (R) sub-pixel, a light emitting element 27G (equivalent to the third light emitting element according to an aspect of the invention) provided corresponding to the green (G) sub-pixel, and a light emitting element 27B (equivalent to the second light emitting element according to an aspect of the invention) provided corresponding to the blue (B) sub-pixel. In addition, the organic EL apparatus 111 has the sealing member 38 sealing each light emitting element 27R, 27G, and 27B of the substrate 31 and the sealing substrate 20 pinching the sealing member 38 and bonded to the substrate 31.

The substrate 31 is formed of, for example, glass or the like, and has a bottom emission structure in which the emitted light from each light emitting element 27R, 27G, and 27B is taken out from the substrate 31. Here, without being limited to the bottom emission structure, application is also possible to the top emission structure. In addition, although not shown in FIG. 7, similarly to the above-described first embodiment, the circuit element layer 43 including: a pixel circuit or a peripheral circuit, which includes the driving TFT 23 for making each light emitting element 27R, 27G, and 27B emit light; wiring; or the like is provided on the substrate 31.

The light emitting element 27R has a functional layer 26R including a light emitting layer 164 capable of obtaining red emitted light between the anode 24R and the cathode 25 which is a shared cathode. The light emitting element 27G has a functional layer 26G including a light emitting layer 165 capable of obtaining green emitted light between the anode 24G and the cathode 25 which is a shared cathode. The light emitting element 27B has the functional layer 26R including a light emitting layer 177 capable of obtaining blue emitted light between the anode 24B and the cathode 25 which is a shared cathode.

The red light emitting layer 164 is formed using the liquid phase process on the anode 24R surrounded by the bank 62. The green light emitting layer 165 is formed using the same liquid phase process on the anode 24G surrounded by the bank 62. The blue light emitting layer 177 is formed using the gas phase process to straddle each light emitting element 27R, 27G, and 27B.

More specifically, as shown in FIG. 8, the light emitting element 27R has the anode 24R, and, formed in order on the anode 24R using the liquid phase process, a hole injecting layer 163, a first hole transporting layer 171, and a red light emitting layer 164 as a first light emitting layer, and, formed in order using the gas phase process, an intermediate layer 174, a second hole transporting layer 176, a red light emitting layer 177 as a second light emitting layer, an electron transporting layer 178, an electron injecting layer 179, and the cathode 25. Similarly, the light emitting element 27G has the anode 24G, and, formed in order on the anode 24G using the liquid phase process, the hole injecting layer 163, the first hole transporting layer 171, and a green light emitting layer 165 as a third light emitting layer, and, formed in order using the gas phase process, the intermediate layer 174, the second hole transporting layer 176, a blue light emitting layer 177, the electron transporting layer 178, the electron injecting layer 179, and the cathode 25. The light emitting element 27B has the anode 24B, and, formed on the anode 24B using the liquid phase process, the hole injecting layer 163, and, formed in order using the gas phase process, the intermediate layer 174, the second hole transporting layer 176, the blue light emitting layer 177, the electron transporting layer 178, the electron injecting layer 179, and the cathode 25.

Similarly to the hole injecting layer 63 in the first embodiment, the hole injecting layer 163 common to each light emitting element 27R, 27G, and 27B is formed using hole injecting layer forming ink including polymer hole injecting material.

Similarly to the hole transporting layer 71 in the first embodiment, the first hole transporting layer 171 common to the light emitting element 27R, and the light emitting element 27G is formed using hole transporting layer forming ink including polymer hole transporting material. Here, the hole transporting material is not limited to a polymer material, and may be a low molecular weight material.

Similarly to the light emitting layer 64 in the first embodiment, the red light emitting layer 164 of the light emitting element 27R and the green light emitting layer 165 of the light emitting element 27G are formed using light emitting layer forming ink including a low molecular weight host material and a dopant.

The intermediate layer 174 common to each light emitting element 27R, 27G, and 27B includes the low molecular weight host material included in the light emitting layer 164 and the light emitting layer 165, which are coating films, and is formed using a gas phase process such as, for example, the vapor deposition method.

The second hole transporting layer 176 common to each light emitting element 27R, 27G, and 27B includes the hole transporting material of low molecular weight and is formed using a gas phase process such as, for example, the vapor deposition method. Examples of the hole transporting material of low molecular weight include copper phthalocyanine(TAPC), 1,1-bis[4-(di-p-tolyl)amini phenyl]cyclohexane(TPD), N,N′-diphenyl-N,N′-bis-(3-methylphenyl)-1,1′-biphenyl-4,4′-diamine, N,N′-diphenyl-N,N′-bis-(1-naphthyl)-1,1′-biphenyl-4,4′-diamine(α-NPD), m-MTDATA, 4,4′,4″-tris(3-methylphenylamino)triphenylamine(2-TNATA), 4,4′,4″-tris(N,N-(2-naphthyl)phenylamino)triphenylamine(TCTA), tris-(4-carbazol-9-yl-phenyl)-amine(spiro-TAD), DPPD(DTP), HTM1, tris-p-tolylamine (HTM2), 1,1-bis[(di-4-tolylamino) phenyl]cyclohexane(TPT1), 1,3,5-tris(4-pyridyl)-2,4,6-triazine(TPTE), triphenylamine tetramers, and the like.

The light emitting layer 177 common to each light emitting element 27R, 27G, and 27B includes the low molecular weight host material and the dopant, which is able to obtain blue emitted light, and is formed using a gas phase process such as, for example, the vapor deposition method.

The electron transporting layer 178 common to each light emitting element 27R, 27G, and 27B includes an electron transporting material of low molecular weight in the same manner as the electron transporting layer 78 of the first embodiment and is formed using a gas phase process such as, for example, the vapor deposition method.

The electron injecting layer 179 common to each light emitting element 27R, 27G, and 27B includes an electron injecting material in the same manner as the electron injecting layer 79 of the first embodiment and is formed using a gas phase process such as, for example, the vapor deposition method.

Since this organic EL apparatus 111 has the intermediate layer 174, which is a vapor deposition film, including a low molecular weight host material included in the light emitting layers 164 and 165 between the light emitting layers 164 and 165, which are coating films, and the light emitting layer 177, which is a vapor deposition film, and in common with the light emitting elements 27R and 27G, it is possible to transport the electrons injected from the cathode 25 to the light emitting layers 164 and 165 with high efficiency. Accordingly, the light emitting elements 27R and 27G are able to obtain the original red and green emitted light even when there is the light emitting layer 177 having a different light emission color.

On the other hand, since the light emitting element 27B has the electron transporting layer 178 on the cathode 25 side in contact with the blue light emitting layer 177 and, along with this, has a second hole transporting layer 176 on the anode 24B side, it is possible to obtain blue emitted light by injecting holes and electrons with good balance as a carrier.

That is, the organic EL apparatus 111 of the present embodiment has a configuration using the liquid phase process and the gas phase process, separately coating the red light emitting layer 164 and the green light emitting layer 165, forming the blue light emitting layer 177 in common without being coated separately, and being able to selectively obtain respective light emission colors of red, green, and blue. In particular, the red and green light emitting layers 164 and 165 formed by the liquid phase process have reached a level for practical use in the points of light emitting brightness and light emitting lifetime; however, the blue light emitting layer formed by the liquid phase process has not yet reached a level for practical use. In the present embodiment, since the blue light emitting layer 177 is formed by gas phase process to reach a level for practical use, it is possible to provide the organic EL apparatus 111 which reaches the level for practical use in the points of light emitting brightness and light emitting lifetime.

### Method of Manufacturing Organic El Apparatus

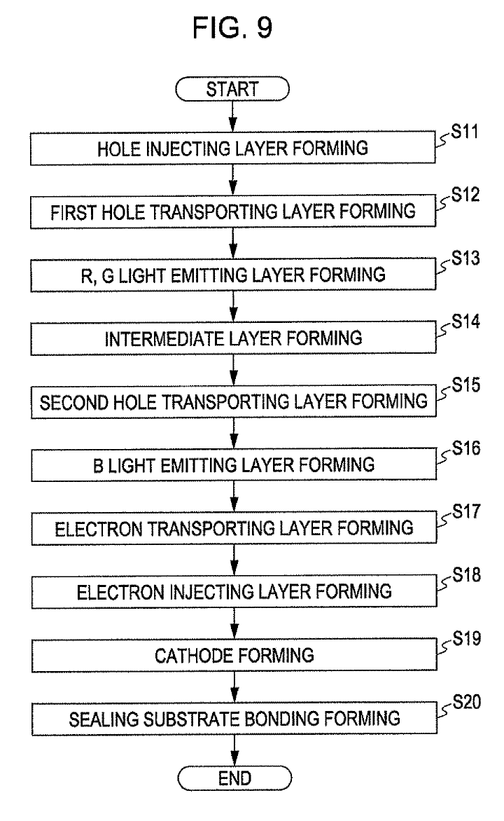

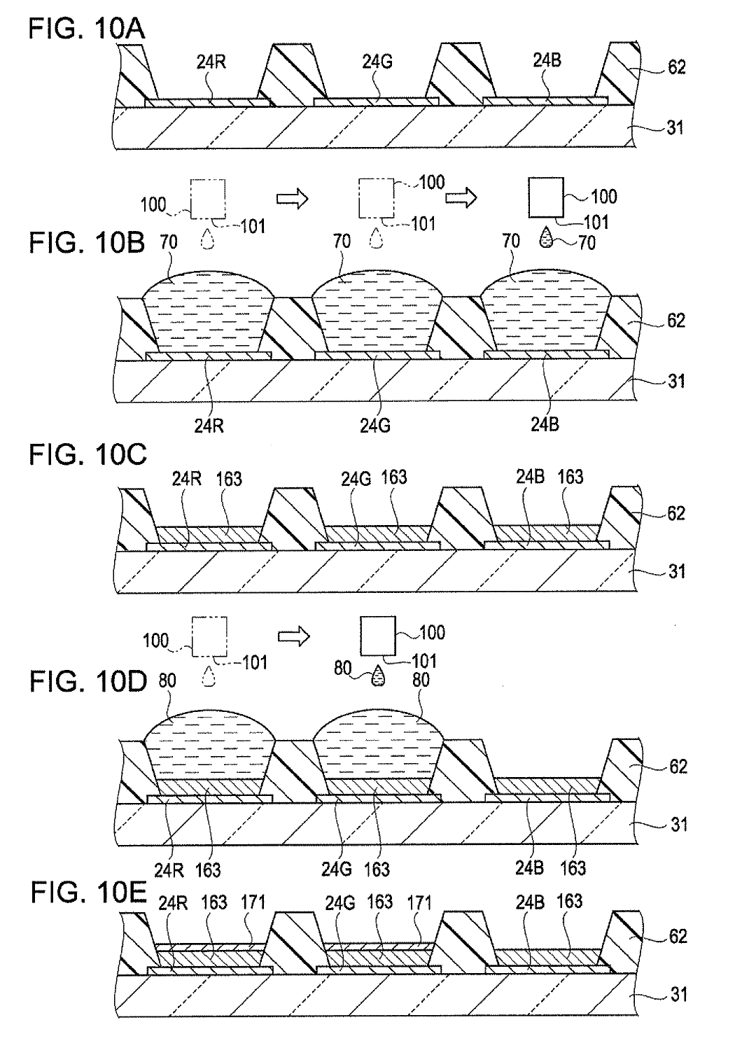

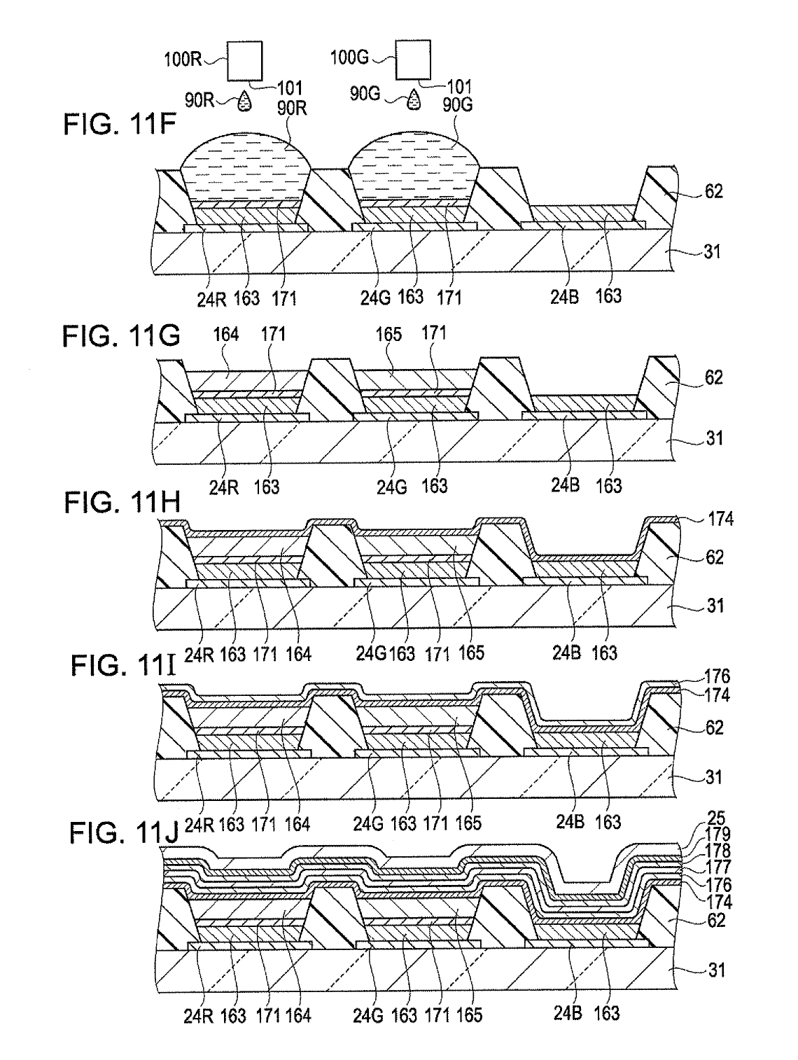

Next, more specific description will be given of the method of manufacturing the organic EL apparatus of the second embodiment with reference to FIGS. 9 to 11. FIG. 9 is a flowchart showing a method of manufacturing the organic EL apparatus of the second embodiment, and FIGS. 10A to 10E and FIGS. 11F to 11J are schematic cross-sectional views showing the method of manufacturing the organic EL apparatus of the second embodiment. Here, in FIGS. 10 and 11, the display of the circuit element layer 43 in the substrate 31 is omitted. It is possible to use a known method as the forming method of the circuit element layer 43 including the driving TFT 23.

As shown in FIG. 9, the method of manufacturing the organic EL apparatus 111 of the present embodiment is provided with a hole injecting layer forming step (step S11), a first hole transporting layer forming step (step S12), an R and G light emitting layer forming step (step S13), an intermediate layer forming step (step S14), a second hole transporting layer forming step (step S15), a B light emitting layer forming step (step S16), an electron transporting layer forming step (step S17), an electron injecting layer forming step (step S18), a cathode forming step (step S19), and a sealing substrate bonding step (step S20).

First, as shown in FIG. 10A, the substrate 31, which has the anodes 24R, 24G, and 24B corresponding to the red, green, and blue light emitting pixels, and the bank 62 formed so as to partition the anodes 24R, 24G, and 24B respectively, was prepared. In the first embodiment, first, the insulating layer 66 for electrically insulating the anodes 24R, 24G, and 24B was provided (refer to FIG. 3); however, in the present embodiment, the forming of the insulating layer 66 is omitted. In addition, the bank 62 has an insulating property, and, along with this, is formed using, for example, a photosensitive acrylic based resin or polyimide resin including a liquid repellent material exhibiting liquid repellency with respect to the functional layer forming ink to be used later. Thus, a CF₄ plasma treatment imparting liquid repellency to the bank 62 is not necessary. Here, to remove residue remaining on the surface of the anodes 24R, 24G, and 24B at the time of forming the bank 62, for example, a UV ozone treatment (treatment removing residue formed of organic matter using ozone generated by the irradiation of ultraviolet rays) may be performed.

In the hole injecting layer forming step (step S11) of FIG. 9, as shown in FIG. 10B, a hole injecting layer forming ink 70 is coated in the respective regions partitioned by the bank 62. The coating of the hole injecting layer forming ink 70 uses the ink jet method (droplet discharge method) in which an ink jet head 100 having a plurality of nozzles 101 and the substrate 31 are arranged in opposition and, while these are moving relatively, the hole injecting layer forming ink 70 is discharged as droplets from the plurality of nozzles 101. The coated hole injecting layer forming ink 70 fills the regions partitioned by the bank 62 evenly and is raised by surface tension. Then, by performing a drying process involving performing a heating process and a decompression process on the coated hole injecting layer forming ink 70, as shown in FIG. 10C, the hole injecting layer 163 in contact with the anodes 24R, 24G, and 24B is formed. The hole injecting layer forming ink 70 includes the hole injecting material and the stereoscopic described in the first embodiment, and it is possible to use a 1.0 wt % PEDOT/PSS aqueous dispersion medium, for example. The film thickness of the hole injecting layer 163 is not particularly limited; however, approximately 5 nm or more to 150 nm or less is preferable and approximately 10 nm or more and 100 nm or less is more preferable. Next, the process proceeds to step S12.

In the first hole transporting layer forming step (step S12) of FIG. 9, as shown in FIG. 10D, a hole transporting layer forming ink 80 is coated on the hole injecting layer 163 of the anodes 24R and 24G partitioned by the bank 62. The coating of the hole transporting layer forming ink 80 also uses the ink jet head 100. The hole transporting layer forming ink 80 includes the polymer hole transporting material described in the first embodiment, and it is possible to use a tetramethyl benzene solution including 1.5 wt % of a triphenylamine based polymer, for example. The coated hole transporting layer forming ink 80 fills the regions partitioned by the bank 62 evenly and is raised by surface tension. Then, by performing a drying process involving performing a heating process and a decompression process on the coated hole transporting layer forming ink 80, as shown in FIG. 10E, the first hole transporting layer 171 in contact with the hole injecting layer 163 formed with respect to the anodes 24R and 24G is formed. The film thickness of the first hole transporting layer 171 is not particularly limited; however, approximately 5 nm or more and 100 nm or less is preferable, and approximately 10 nm or more and 50 nm or less is more preferable.

The first hole transporting layer 171 is not formed on the hole injecting layer 163 formed corresponding to the anode 24B. Next, the process proceeds to step S13.

In the R and G light emitting layer forming step (step S13) of FIG. 9, as shown in FIG. 11F, a light emitting layer forming ink 90R is coated on the first hole transporting layer 171 of the anode 24R partitioned by the bank 62. In addition, a light emitting layer forming ink 90G is coated on the first hole transporting layer 171 of the anode 24G partitioned by the bank 62. The coating of the light emitting layer forming inks 90R and 90G also uses ink jet heads 100R and 100G filled with inks corresponding thereto respectively. The light emitting layer forming inks 90R and 90G include the low molecular weight host material and the dopant described in the first embodiment, and it is possible to use a tetramethyl benzene solution including 1.2 wt % of CBP and mCP as the host material and three types of dopant Irppy3, for example. The coated light emitting layer forming inks 90R and 90G fill the regions partitioned by the bank 62 evenly and are raised by surface tension. Then, by performing a drying process involving performing a decompression process and a heating process on the coated light emitting layer forming inks 90R and 90G, as shown in FIG. 11G, the red light emitting layer 164 in contact with the first hole transporting layer 171 on the anode 24R and the green light emitting layer 165 in contact with the first hole transporting layer 171 on the anode 24G are coated separately and formed. The film thicknesses of the light emitting layers 164 and 165 are not particularly limited; however, approximately 10 nm or more and 150 nm or less is preferable, and approximately 20 nm or more and 100 nm or less is more preferable. Next, the process proceeds to step S14.

In the intermediate layer forming step (step S14) of FIG. 9, as shown in FIG. 11H, the red light emitting layer 164, the green light emitting layer 165, the hole injecting layer 163 on the anode 24B, and the intermediate layer 174 covering the bank 62 are formed by the vapor deposition method which is a gas phase process. The intermediate layer 174 includes a low molecular weight host material included in the red light emitting layer 164 and the green light emitting layer 165, an example of which may include the host material of CBP, mCP, and the like described in the first embodiment. In the same manner as the first embodiment, the thickness of the intermediate layer 174 is preferably approximately 1 nm or more and 5 nm or less. Next, the process proceeds to step S15.

In the second hole transporting layer forming step (step S15) of FIG. 9, as shown in FIG. 11I, the second hole transporting layer 176 covering the intermediate layer 174 is formed by the vapor deposition method which is a gas phase process. The second hole transporting layer 176 includes a hole transporting material of low molecular weight. Examples of the hole transporting material of low molecular weight include α-NPD and the like. The film thickness of the second hole transporting layer 176 is preferably 10 nm to 40 nm. Next, the process proceeds to step S16.

In the B light emitting layer forming step (step S16) of FIG. 9, the blue (B) light emitting layer 177 covering the second hole transporting layer 176 is formed by the vapor deposition method which is a gas phase process. The light emitting layer 177 includes a low molecular weight host material and a dopant, and examples of the low molecular weight host material include CBP(4,4′-bis(9-dicarbazolyl)-2,2′-biphenyl), BAlq(Bis-(2-methyl-8-quinolinolate)-4-(phenylphenolate)) aluminum), mCP(N,N-dicarbazolyl-3,5-benzene: CBP derivative), CDBP(4,4′-bis(9-carbazolyl)-2,2′-dimethyl-biphenyl), DCB(N,N′-Dicarbazolyl-1,4-dimethene-benzene), P06(2,7-bis(diphenylphosphineoxide)-9,9-dimethylfluorene), SimCP(3,5-bis(9-carbazolyl)tetraphenylsilane), UGH3(W-bis(triphenylsilyl)benzene), and the like. In particular, as the host material of the blue light emitting layer 177 formed using a vapor deposition method, it is preferable to use the anthracene derivative.

Examples of the dopant which is able to obtain blue light emission include iridium complexes such as FIrpic (Iridium-bis(4,6-difluorophenyl-pyridinato-N,C,2,)-picolinate), Ir(pmb)3(Iridium-tris(1-phenyl-3-methylbenzimidazolin-2-ylidene-C,C(2)′), FIrN4(((Iridium(III)bis(4,6-difluorophenylpyridinato)5-(pyridin-2-yl)-tetrazolate), Firtaz((Iridium(III)bis-(4,6-difluorophenylpyridinato) (5-(pyridine-2-yl)-1,2,4-triazo-late), and the like, and it is possible to obtain blue phosphorescent light by adding these to the previously described host materials.

In addition, styrylbenzene derivatives such as 1,4-bis(2-methylstyryl)benzene, 1,4-(3-methylstyryl)benzene, 1,4-bis-(2-methylstyryl)benzene, 1,4-(3-methylstyryl)benzene, 1,4-bis(4-methylstyryl)benzene, distyryl benzene, 1,4-bis(2-ethylstyryl)benzene, 1,4-bis(3-ethylstyryl)benzene, and 1,4-bis(2-methylstyryl)-2-methylbenzene are used as the dopant, and it is possible to obtain blue fluorescent light by adding these to the previously described host materials.

The film thickness of the light emitting layer 177 is not particularly limited; however, 20 nm or more and 60 nm or less is preferable. Next, the process proceeds to step S17.

In the electron transporting layer forming step (step S17) of FIG. 9, the electron transporting layer 178 covering the blue light emitting layer 177 is formed by the vapor deposition method which is a gas phase process. The configuration of the electron transporting layer 178 is the same as the electron transporting layer 78 of the first embodiment. The film thickness of the electron transporting layer 178 is not particularly limited; however, approximately 1 nm or more and 100 nm or less is preferable, and approximately 5 nm or more and 50 nm or less is more preferable. Next, the process proceeds to step S18.

In the electron injecting layer forming step (step S18) of FIG. 9, the electron injecting layer 179 covering the electron transporting layer 178 is formed by the vapor deposition method which is a gas phase process. The configuration of the electron injecting layer 179 is the same as the electron injecting layer 79 of the first embodiment. The film thickness of the electron injecting layer 179 is not particularly limited; however, approximately 0.01 nm or more and 100 nm or less is preferable, and approximately 0.1 nm or more and 10 nm or less is more preferable. Next, the process proceeds to step S19.

In the cathode forming step (step S19) of FIG. 9, the cathode 25 covering the electron injecting layer 179 is formed by the vapor deposition method which is a gas phase process. The film thickness of the cathode 25 is not particularly limited; however, approximately 50 nm or more and 1000 nm or less is preferable, and approximately 100 nm or more and 500 nm or less is more preferable. In this manner, as shown in FIG. 11I, the functional layer 26R including a red light emitting layer 164 between the anode 24R and the cathode 25 is formed, the functional layer 26G including a green light emitting layer 165 between the anode 24G and the cathode 25 is formed, and a functional layer 26B including a blue light emitting layer 177 between the anode 243 and the cathode 25 is formed. Next, the process proceeds to step S20.

In the sealing substrate bonding step (step S20) of FIG. 9, as shown in FIG. 7, the substrate 31 and the sealing substrate 20 are bonded via the sealing member 38 having a bonding property and formed of a transparent resin covering and sealing each light emitting element 27R, 27G, and 27B of the substrate 31. In this manner, the organic EL apparatus 111 is completed.

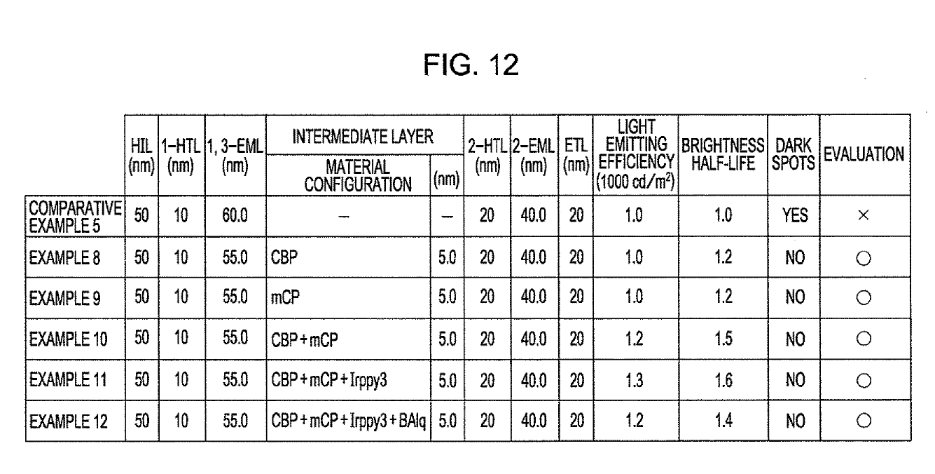

Next, description will be given with reference to FIG. 12 specifically showing Comparative Example 5 and Examples 8 to 12. FIG. 12 is a table showing the configuration of each layer and the evaluation results of the element characteristics in the Comparative Example 5 and the Examples 8 to 12 in the second embodiment. Here, in the table of FIG. 12, HIL indicates the hole injecting layer, 1-HTL indicates the first hole transporting layer, 1,3-EML indicates the red light emitting layer which is the first light emitting layer and the green light emitting layer which is the third light emitting layer, 2-HTL indicates the second hole transporting layer, 2-EML indicates the blue light emitting layer which is the second light emitting layer, and ETL indicates the electron transporting layer. In addition, since the configuration of the electron injecting layer is the same in Comparative Example 5 and Examples 8 to 12, description thereof is omitted in the table.

In the same manner as the first embodiment, the evaluation of the element characteristics of Comparative Example 5 and Examples 8 to 12 was determined according to three items of light emitting efficiency, brightness half-life, and dark spots. The light emitting efficiency is quantified on the basis of Comparative Example 5 based on the current amount when the brightness is 1000 cd/m². The brightness half-life is quantified on the basis of Comparative Example 5 based on the energization time when the brightness is 500 cd/m², which is half of 1000 cd/m². The dark spots are set on the basis of the presence or absence of the generation thereof at the time point when the brightness was reduced by half. The evaluation takes these three items together and indicates one of “X”, not at a level for practical use, “◯”, at a level for practical use, and “⊙”, exceeds a level for practical use.

### Comparative Example 5

As shown in FIG. 12, with respect to organic EL apparatus 111 of the above-described second embodiment, the organic EL apparatus of Comparative Example 5 is configured with the intermediate layer 174 between the light emitting layers 164 and 165 which are coating films and the second hole transporting layer 176 which is a vapor deposition film omitted.

Specifically, the hole injecting layer 163 includes a polymer PEDOT/PSS as the hole injection material, and has a film thickness of 50 nm. The first hole transporting layer 171 includes a triphenylamine based polymer (TFP) which is a polymer hole transporting material, and has a film thickness of 10 nm. The red light emitting layer 164 as the first light emitting layer includes CBP and mCP, which are a low molecular weight host material, and PtOEP as the dopant, and has a film thickness of 60 nm. The green light emitting layer 165 as the third light emitting layer includes CBP and mCP, which are a low molecular weight host material, and Irppy3 as the dopant, and has a film thickness of 60 nm. The second hole transporting layer 176 includes α-NPD as a hole transporting material of low molecular weight, and has a film thickness of 20 nm. The blue light emitting layer 177 as the second light emitting layer includes CBP which is a low molecular weight host material, and FIrpic as the dopant, and has a film thickness of 40 nm. The electron transporting layer 178 includes BAlg as a hole transporting material of low molecular weight, and has a film thickness of 20 nm. Additionally, the film thickness of the electron injecting layer 179 is 5 nm and the film thickness of the cathode 25 is 200 nm.

The hole injecting layer 163, the first hole transporting layer 171, and the light emitting layers 164 and 165 are respectively formed using the liquid phase process (ink jet method) and the second hole transporting layer 176, the light emitting layer 177, the electron transporting layer 178, the electron injecting layer 179, and the cathode 25 are respectively formed using the gas phase process (vapor deposition method).

### Example 8

As shown in FIG. 12, with respect to Comparative Example 5, in Example 8, the intermediate layer 174 is formed with the gas phase process (vapor deposition method) between the light emitting layers 164 and 165 which are coating films and the second hole transporting layer 176 which is a vapor deposition film. The intermediate layer 174 includes CBP which is a low molecular weight host material included in the light emitting layers 164 and 165, and has a film thickness of 5.0 nm. In addition, the film thickness of the light emitting layers 164 and 165 is 55.0 nm, respectively. That is, the total film thickness of the light emitting layers 164 and 165 and the intermediate layer 174 is 60 nm.

### Example 9

As shown in FIG. 12, with respect to Example 8, in Example 9, the low molecular weight host material configuring the intermediate layer 174 is set as mCP.

### Example 10

As shown in FIG. 12, with respect to Example 8, Example 10 includes CBP and mCP as the low molecular weight host material configuring the intermediate layer 174.

### Example 11

As shown in FIG. 12, with respect to Example 8, Example 11 includes CBP and mCP which are the low molecular weight host material and Irppy3 which is the dopant as the components configuring the intermediate layer 174.

### Example 12

As shown in FIG. 12, with respect to Example 8, Example 12 includes CBP and mCP which are the low molecular weight host material, Irppy3 which is the dopant, and BAlq which is an electron transporting material as the components configuring the intermediate layer 174.

Since dark spots were confirmed when the brightness was halved without the intermediate layer 174 which is a vapor deposition film between the light emitting layers 164 and 165 which are coating films and the second hole transporting layer 176 which is a vapor deposited film, the evaluation of Comparative Example 5 was “X”.

Since Example 8 and Example 9 in which the intermediate layer 174 which is a vapor deposition film between the light emitting layers 164 and 165, which are coating films, and the second hole transporting layer 176 which is a vapor deposition film had a light emitting efficiency equal with respect to Comparative Example 5 while having 1.2 times the brightness half-life and dark spots were also not confirmed, the evaluation thereof is “◯”.

With respect to Comparative Example 5, since Example 10 to Example 12 including a low molecular weight host material of two species in the intermediate layer 174 exhibited excellent numerical values in light emitting efficiency and brightness half-life and dark spots were also not confirmed, the evaluation thereof is “◯”. In particular, with respect to Comparative Example 5, Example 11 further including Irppy3, which is a dopant, in the intermediate layer 174 is more preferable with a light emitting efficiency of 1.3 times and a brightness half-life of 1.6 times.

According to the above-described second embodiment, the following effects can be obtained.

(1) According to the organic EL apparatus 111 and the manufacturing method thereof of the above-described second embodiment, the configuration separately coats the red light emitting layer 164 and the green light emitting layer 165 using the liquid phase process, further forms the blue light emitting layer 177 in common using the gas phase process (vapor deposition method), and is able to selectively obtain respective light emission colors of red, green, and blue. Then, the red and green light emitting layers 164 and 165 formed by the liquid phase process reached a level for practical use in the points of light emitting brightness and light emitting lifetime. In addition, by forming the blue light emitting layer 177 by the gas phase process, the blue light emitting layer 177 was made to reach a level for practical use. Accordingly, it is possible to provide the organic EL apparatus 111 provided with the light emitting elements 27R, 27G, and 27B reaching the level for practical use in the points of light emitting brightness and light emitting lifetime, in the respective sub-pixels 34. In addition, since a deposition mask is not necessary in comparison with a case where the red, green, and blue light emitting layers are individually formed as films using, for example, a deposition mask, it is possible to manufacture the organic EL apparatus 111 with high efficiency.

(2) In addition, since the intermediate layer 174 which is a vapor deposition film includes the low molecular weight host material with the electron transporting property included in the light emitting layers 164 and 165, which are coating films, it is possible to transport the electrons injected from the cathode 25 side to the light emitting layers 164 and 165 with high efficiency. In addition, since the thickness of the intermediate layer 174 is 1 nm or more and 5 nm or less, it is possible to suppress an increase in the driving voltage or a decrease in the light emitting efficiency caused by forming the intermediate layer 174 between the light emitting layers 164 and 165 and the second hole transporting layer 176.

(3) In addition, in the blue light emitting layer 177, since the second hole transporting layer 176 is formed by a gas phase process on the anode 24B side and the electron transporting layer 178 is formed by the same gas phase process on the cathode 25 side, it is possible to transport the holes which are the carrier and the electrons to the light emitting layer 177 with high efficiency and obtain blue emitted light.

### Third Embodiment

### Configuration of Organic EL Apparatus

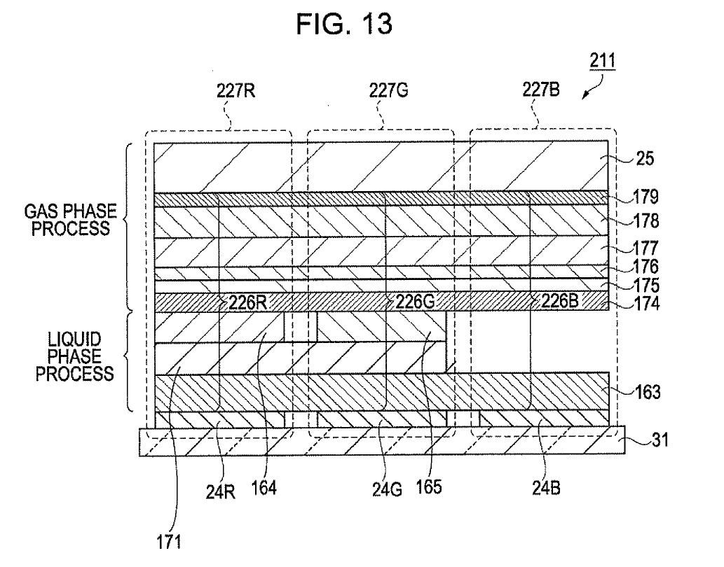

Next, description will be given of the organic EL apparatus of the third embodiment with reference to FIG. 13. FIG. 13 is a schematic cross-sectional view showing the configuration of the light emitting element in the organic EL apparatus of the third embodiment. With respect to the organic EL apparatus 111 of the second embodiment, in the organic EL apparatus of the third embodiment, the configuration of each of the red (R), green (G), and blue (B) light emitting elements is different. Here, where the configuration is the same as the second embodiment, the same reference numerals will be given and the detailed description thereof will be omitted.

As shown in FIG. 13, an organic EL apparatus 211 of the present embodiment is provided with a light emitting element 227R having a functional layer 226R between the anode 24R and the cathode 25 which is a shared cathode, a light emitting element 227G having a functional layer 226G between the anode 24G and the cathode 25 which is a shared cathode, and a light emitting element 227B having a functional layer 226B between the anode 24B and the cathode 25 which is a shared cathode.

The functional layer 226R of the light emitting element 227R has, formed in order from the anode 24R side using the liquid phase process, the hole injecting layer 163, the first hole transporting layer 171, and the red light emitting layer 164 as the first light emitting layer. In addition, the functional layer 226R has, formed in order using the gas phase process, the intermediate layer 174, a carrier adjusting layer 175, the second hole transporting layer 176, the blue light emitting layer 177 as the second light emitting layer, the electron transporting layer 178, and the electron injecting layer 179.

The functional layer 226G of the light emitting element 227G has, formed in order from the anode 24G side using the liquid phase process, the hole injecting layer 163, the first hole transporting layer 171, and the green light emitting layer 165 as the third light emitting layer. In addition, the functional layer 226G has, formed in order using the gas phase process, the intermediate layer 174, the carrier adjusting layer 175, the second hole transporting layer 176, the blue light emitting layer 177 as the second light emitting layer, the electron transporting layer 178, and the electron injecting layer 179.

The functional layer 226B of the light emitting element 227B has the hole injecting layer 163 formed from the anode 24B side using the liquid phase process, and, formed in order using the gas phase process, the intermediate layer 174, the carrier adjusting layer 175, the second hole transporting layer 176, the blue light emitting layer 177 as the second light emitting layer, the electron transporting layer 178, and the electron injecting layer 179.

In other words, with respect to the organic EL apparatus 111 of the second embodiment, the organic EL apparatus 211 of the present embodiment is different in the point of having the carrier adjusting layer 175 between the intermediate layer 174 which is a vapor deposition film and the second hole transporting layer 176.

The carrier adjusting layer 175 is configured to include a metal compound having an electron transporting property. Examples of the metal compound include alkali metals and alkaline earth metals with an excellent electron transporting property.

Examples of the alkali metal compounds include alkali metal salts such as LiF, Li₂CO₃, LiCl, NaF, Na₂CO₃, NaCl, CsF, Cs₂CO₂, CsCl, and the like. In addition, examples of the alkaline earth metal compounds include alkaline earth metal salts such as CaF₂, CaCO₃, SrF₂, SrCO₃, BaF₂, BaCO₃, and the like.

In particular, from the point of having an excellent electron transporting property, the use of cesium carbonate (Cs₂CO₃) is preferable.

The film thickness of the carrier adjusting layer 175 is preferably 0.2 nm or more to 1.0 nm or less. In this manner, it is possible to more efficiently transport electrons to the red light emitting layer 164 and the green light emitting layer 165 respectively through the intermediate layer 174. In addition, by arranging the carrier adjusting layer 175 between the intermediate layer 174 and the second hole transporting layer 176, it is possible to suppress an increase in the driving voltage or a decrease in the light emitting efficiency of the blue light emitting layer 177 as the second light emitting layer.

### Method of Manufacturing Organic EL Apparatus

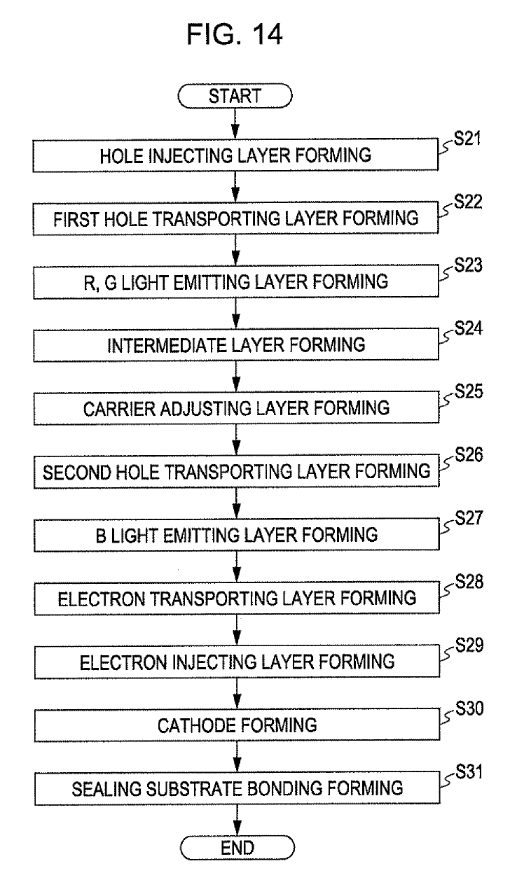

Next, description will be given of the method of manufacturing the organic EL apparatus of the third embodiment with reference to FIG. 14. FIG. 14 is a flowchart showing the method of manufacturing the organic EL apparatus of the third embodiment.

The method of manufacturing the organic EL apparatus 211 of the present embodiment is provided with a hole injecting layer forming step (step S21), a first hole transporting layer forming step (step S22), an R and G light emitting layer forming step (step S23), an intermediate layer forming step (step S24), a carrier adjusting layer forming step (step S25), a second hole transporting layer forming step (step S26), a B light emitting layer forming step (step S27), an electron transporting layer forming step (step S28), an electron injecting layer forming step (step S29), a cathode forming step (step S30), and a sealing substrate bonding step (step S31). In other words, with respect to the method of manufacturing the organic EL apparatus 111 of the second embodiment, the method of manufacturing the organic EL apparatus 211 of the present embodiment is different in the point of having an added carrier adjusting layer forming step. Accordingly, hereafter, description will be given of the step which is different to the second embodiment.

In the carrier adjusting layer forming step (step S25) of FIG. 14, the carrier adjusting layer 175 covering the intermediate layer 174 which is a vapor deposition film is formed by the vapor deposition method which is a gas phase process. The carrier adjusting layer 175 includes an alkali metal compound or an alkaline earth metal compound having an electron transporting property as described above, and, for example, is configured by forming cesium carbonate such that the film thickness becomes approximately 0.5 nm using the vapor deposition method.

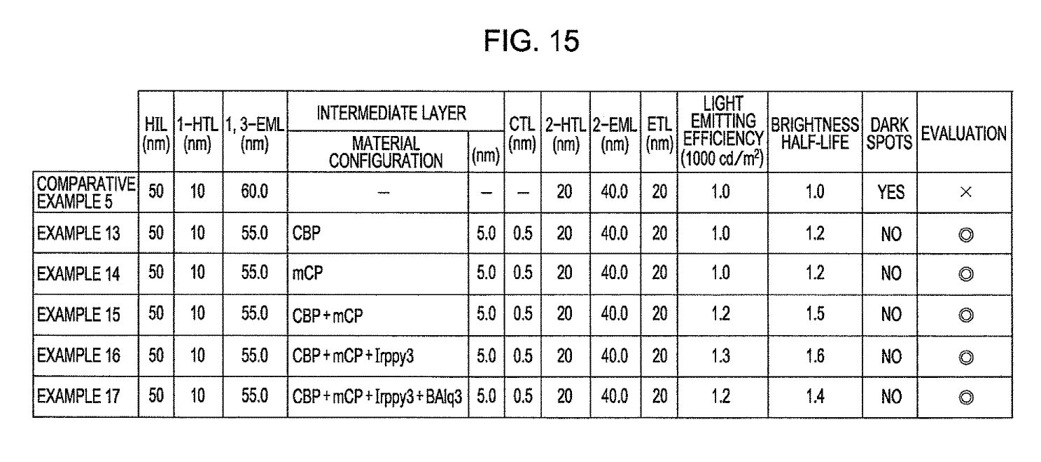

Next, description will be given using specific Comparative Examples and Examples with reference to FIG. 15. FIG. 15 is a table showing the configuration of each layer and the evaluation results of the element characteristics in the Comparative Example 5 and the Examples 13 to 17 in the third embodiment. Here, in the table of FIG. 15, HIL indicates the hole injecting layer, 1-HTL indicates the first hole transporting layer, 1,3-EML indicates the red light emitting layer which is the first light emitting layer and the green light emitting layer which is the third light emitting layer, CTL indicates the carrier adjusting layer, 2-HTL indicates the second hole transporting layer, 2-EML indicates the blue light emitting layer which is the second light emitting layer, and ETL indicates the electron transporting layer. In addition, since the configuration of the electron injecting layer is the same in Comparative Example 5 and Examples 13 to 17, description thereof is omitted in the table.

In the same manner as the first embodiment, the evaluation of the element characteristics of Comparative Example 5 and Examples 13 to 17 was determined according to three items of light emitting efficiency, brightness half-life, and dark spots. The light emitting efficiency is quantified on the basis of Comparative Example 5 based on the current amount when the brightness is 1000 cd/m². The brightness half-life is quantified on the basis of Comparative Example 5 based on the energization time when the brightness is 500 cd/m², which is half of 1000 cd/m². The dark spots are set on the basis of the presence or absence of the generation thereof at the time point when the brightness was reduced by half. The evaluation takes these three items together and indicates one of “X”, not at a level for practical use, “◯”, at a level for practical use, and “⊙”, exceeds a level for practical use.

### Comparative Example 5

As shown in FIG. 15, with respect to organic EL apparatus 211 of the above-described third embodiment, Comparative Example 5 is configured with the intermediate layer 174 and the carrier adjusting layer 175 between the light emitting layers 164 and 165 which are coating films and the second hole transporting layer 176 which is a vapor deposition film omitted.

Since the specific configuration of each layer has been described in the second embodiment, a detailed explanation will be omitted here.

The hole injecting layer 163, the first hole transporting layer 171, and the light emitting layers 164 and 165 are respectively formed using the liquid phase process (ink jet method) and the second hole transporting layer 176, the light emitting layer 177, the electron transporting layer 178, the electron injecting layer 179, and the cathode 25 are respectively formed using the gas phase process (vapor deposition method).

### Example 13

As shown in FIG. 15, with respect to Comparative Example 5, in Example 13, the intermediate layer 174 and the carrier adjusting layer 175 are formed with the gas phase process (vapor deposition method) between the light emitting layers 164 and 165 which are coating films and the second hole transporting layer 176 which is a vapor deposition film. The intermediate layer 174 includes CBP which is a low molecular weight host material included in the light emitting layers 164 and 165, and has a film thickness of 5.0 nm. In addition, the film thickness of the light emitting layers 164 and 165 is 55.0 nm, respectively. That is, the total film thickness of the light emitting layers 164 and 165 and the intermediate layer 174 is 60 nm. The carrier adjusting layer 175 includes cesium carbonate which is an alkali metal compound having an electron transporting property, and the film thickness thereof is 0.5 nm.

### Example 14

As shown in FIG. 15, with respect to Example 13, in Example 14, the low molecular weight host material configuring the intermediate layer 174 is set as mCP.

### Example 15

As shown in FIG. 15, with respect to Example 13, Example 15 includes CBP and mCP as the low molecular weight host material configuring the intermediate layer 174.

### Example 16

As shown in FIG. 15, with respect to Example 13, Example 16 includes CBP and mCP which are the low molecular weight host material and Irppy3 which is the dopant as the components configuring the intermediate layer 174.

### Example 17

As shown in FIG. 15, with respect to Example 13, Example 17 includes CBP and mCP which are the low molecular weight host material, Irppy3 which is the dopant, and BAlq which is an electron transporting material as the components configuring the intermediate layer 174.

Since dark spots were confirmed when the brightness was halved without the intermediate layer 174 which is a vapor deposition film and the carrier adjusting layer 175 between the light emitting layers 164 and 165 which are coating films and the second hole transporting layer 176 which is a vapor deposited film, the evaluation of Comparative Example 5 was “X”.

Example 13 and Example 14 in which the intermediate layer 174 which is a vapor deposition film and the carrier adjusting layer 175 were provided between the light emitting layers 164 and 165, which are coating films, and the second hole transporting layer 176 which is a vapor deposition film had a light emitting efficiency equal with respect to Comparative Example 5 while having 1.2 times the brightness half-life and dark spots were also not confirmed. In addition, by having the carrier adjusting layer 175, since changes of the light emission color of the light emitting layers 164 and 165 when the brightness is reduced by half are suppressed in order to make the transport of the electrons to the red light emitting layer 164 as the first light emitting layer and the green light emitting layer 165 as the third light emitting layer more efficient and to improve the balance of the carrier (holes and electrons) in the light emitting layers 164 and 165, the evaluation thereof is “⊙” which is excellent even in comparison with Example 8 and Example 9 of the second embodiment.

With respect to Comparative Example 5, since Example 15 to Example 17 including a low molecular weight host material of two species in the intermediate layer 174 exhibited excellent numerical values in light emitting efficiency and brightness half-life, dark spots were also not confirmed, and changes of the light emission color when the brightness is reduced by half are suppressed, the evaluation thereof is “⊙”. In particular, with respect to Comparative Example 5, Example 16 further including Irppy3, which is a dopant, in the intermediate layer 174 is more preferable with a light emitting efficiency of 1.3 times and a brightness half-life of 1.6 times.

According to the above-described third embodiment, the following effects can be obtained in addition to the effects (1) to (3) of the above-described second embodiment.

(4) According to the organic EL apparatus 211 of the above-described third embodiment and the manufacturing method thereof, since the carrier adjusting layer 175 having an electron transporting property is formed using the gas phase process in addition to the intermediate layer 174 which is a vapor deposition film between the red light emitting layer 164 and the green light emitting layer 165, which are coating films, and the second hole transporting layer 176, which is a vapor deposition film, it is possible to provide and manufacture the organic EL apparatus 211 having an excellent display quality (light emitting characteristic), in which the carrier balance in the red light emitting layer 164 and the green light emitting layer 165 is favorable and changes in the respective light emission colors are suppressed even after the brightness is reduced by half.

### Fourth Embodiment

### Configuration of Organic EL Apparatus

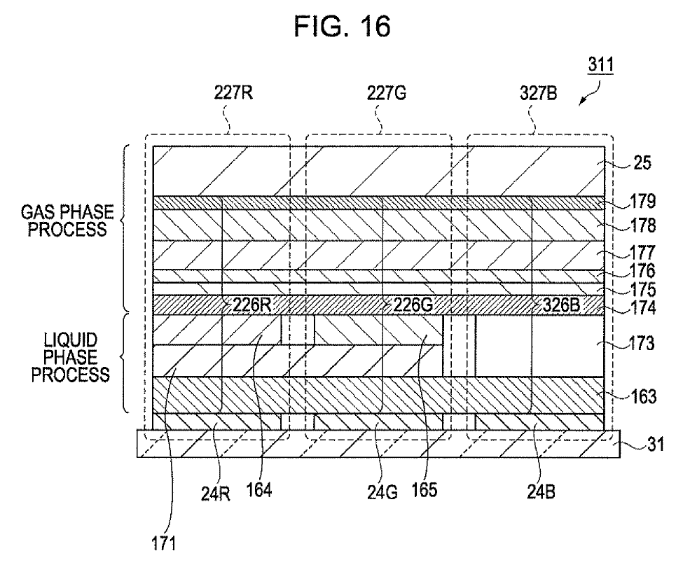

Next, description will be given of the organic EL apparatus of the fourth embodiment with reference to FIG. 16. FIG. 16 is a schematic cross-sectional view showing the configuration of the light emitting element in the organic EL apparatus of the fourth embodiment. With respect to the organic EL apparatus 211 of the third embodiment, in the organic EL apparatus of the fourth embodiment, the configuration of the blue (B) light emitting element is different. Here, where the configuration is the same as the third embodiment, the same reference numerals will be given and the detailed description thereof will be omitted.

As shown in FIG. 16, an organic EL apparatus 311 of the present embodiment is provided with the light emitting element 227R having the functional layer 226R between the anode 24R and the cathode 25 which is a shared cathode, the light emitting element 227G having the functional layer 226G between the anode 24G and the cathode 25 which is a shared cathode, and a light emitting element 327B having a functional layer 326B between the anode 24B and the cathode 25 which is a shared cathode.

Below, detailed description will be given of the configuration of the blue light emitting element 327B which is different to the organic EL apparatus 211 of the above-described third embodiment.

The functional layer 326B of the light emitting element 327B has the hole injecting layer 163 and a third hole transporting layer 173 formed from the anode 24B side using the liquid phase process, and, formed in order using the gas phase process, the intermediate layer 174, the carrier adjusting layer 175, the second hole transporting layer 176, the blue light emitting layer 177 as the second light emitting layer, the electron transporting layer 178, and the electron injecting layer 179.

In other words, with respect to the organic EL apparatus 211 of the third embodiment, the organic EL apparatus 311 of the present embodiment is different in the point of having the third hole transporting layer 173 between the hole injecting layer 163 which is a coating film and the intermediate layer 174 which is a vapor deposition film.

The third hole transporting layer 173 includes a hole transporting material of low molecular weight and is formed by the liquid phase process. For the hole transporting material of low molecular weight, it is possible to use the same ones included in the second hole transporting layer 176 formed by the gas phase process. In this manner, the configuration is able to more efficiently perform transportation of the holes to the blue light emitting layer 177 which is a vapor deposition film as the second light emitting layer. In other words, it is possible to obtain an effect of improving the light emitting efficiency in the blue light emitting layer 177. Examples of the hole transporting material of low molecular weight include the previously described α-NPD and the like.

The film thickness of the third hole transporting layer 173 is not particularly limited; however, approximately 5 nm or more and 100 nm or less is preferable, and approximately 10 nm or more and 50 nm or less is more preferable.

### Method of Manufacturing Organic EL Apparatus

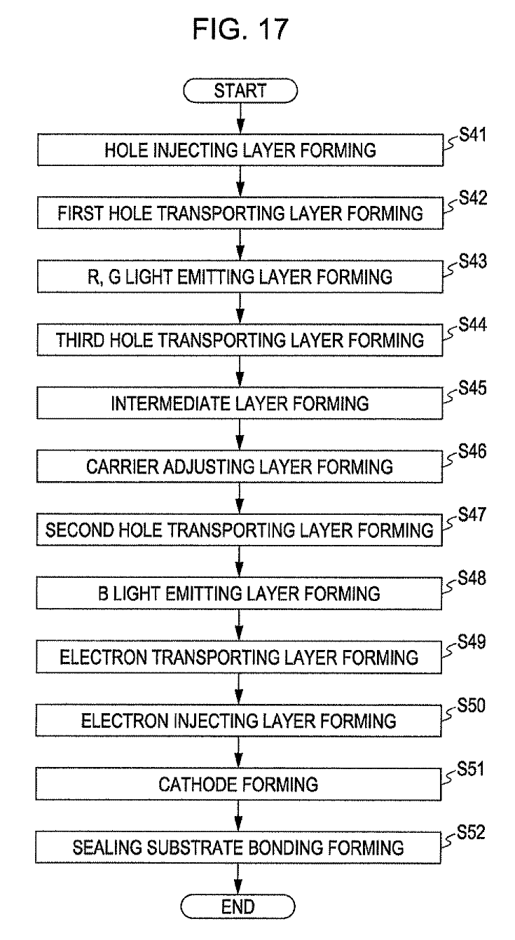

Next, description will be given of the method of manufacturing the organic EL apparatus of the fourth embodiment with reference to FIG. 17. FIG. 17 is a flowchart showing a method of manufacturing the organic EL apparatus of the fourth embodiment.

The method of manufacturing the organic EL apparatus 311 of the present embodiment is provided with a hole injecting layer forming step (step S41), a first hole transporting layer forming step (step S42), an R and G light emitting layer forming step (step S43), a third hole transporting layer forming step (step S44), an intermediate layer forming step (step S45), a carrier adjusting layer forming step (step S46), a second hole transporting layer forming step (step S47), a B light emitting layer forming step (step S48), an electron transporting layer forming step (step S49), an electron injecting layer forming step (step S50), a cathode forming step (step S51), and a sealing substrate bonding step (step S52). In other words, with respect to the method of manufacturing the organic EL apparatus 211 of the third embodiment, the method of manufacturing the organic EL apparatus 311 of the present embodiment is different in the point of having an added third hole transporting layer forming step. Accordingly, hereafter, description will be given of the step which is different to the third embodiment.

In the third hole transporting layer forming step (step S44) of FIG. 17, the third hole transporting layer 173 is formed by the liquid phase process (ink jet method) in the same manner as and in contact with the hole injecting layer 163 formed by the liquid phase process (ink jet method) on the anode 24B. As described above, the third hole transporting layer 173 is formed by coating a third hole transporting layer forming ink including the same hole transporting material of low molecular weight as the second hole transporting layer 176 on a region surrounded by the bank 62, and performing a drying process such as a decompression process or a heating process on the coated third hole transporting layer forming ink. Accordingly, when a heating process such as a drying process is applied again to the temporarily formed third hole transporting layer 173, there is a concern that the hole transporting material of low molecular weight may aggregate and generate partial defects. For this reason, the third hole transporting layer forming step is performed after the R and G light emitting layer forming step (step S43).

Forming the third hole transporting layer 173 including the hole transporting material of low molecular weight using a gas phase process may also be considered; however, since there is a need for selective forming on the anode 24B, the liquid phase process (ink jet method) is adopted in the present embodiment in consideration of productivity.

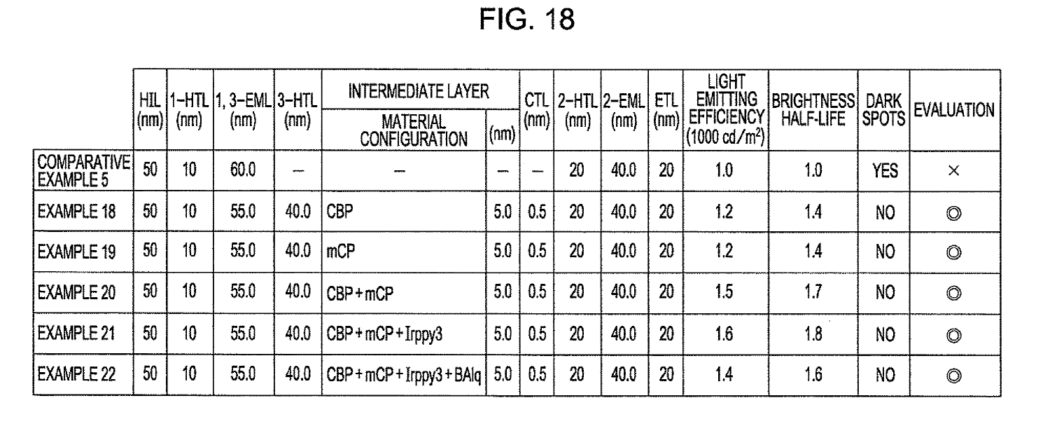

Next, description will be given with reference to FIG. 18 specifically showing Comparative Example 5 and Examples 18 to 22. FIG. 18 is a table showing the configuration of each layer and the evaluation results of the element characteristics in the Comparative Example 5 and the Examples 18 to 22 in the fourth embodiment. Here, in the table of FIG. 18, HIL indicates the hole injecting layer, 1-HTL indicates the first hole transporting layer, 1,3-EML indicates the red light emitting layer which is the first light emitting layer and the green light emitting layer which is the third light emitting layer, 3-HTL indicates the third hole transporting layer, CTL indicates the carrier adjusting layer, 2-HTL indicates the second hole transporting layer, 2-EML indicates the blue light emitting layer which is the second light emitting layer, and ETL indicates the electron transporting layer. In addition, since the configuration of the electron injecting layer is the same in Comparative Example 5 and Examples 18 to 22, description thereof is omitted in the table.

In the same manner as the first embodiment, the evaluation of the element characteristics of Comparative Example 5 and Examples 18 to 22 was determined according to three items of light emitting efficiency, brightness half-life, and dark spots. The light emitting efficiency is quantified on the basis of Comparative Example 5 based on the current amount when the brightness is 1000 cd/m². The brightness half-life is quantified on the basis of Comparative Example 5 based on the energization time when the brightness is 500 cd/m², which is half of 1000 cd/m². The dark spots are set on the basis of the presence or absence of the generation thereof at the time point when the brightness was reduced by half. The evaluation takes these three items together and indicates one of “X”, not at a level for practical use, “◯”, at a level for practical use, and “⊙”, exceeds a level for practical use.

### Comparative Example 5

As shown in FIG. 18, with respect to organic EL apparatus 311 of the above-described fourth embodiment, Comparative Example 5 is configured with the intermediate layer 174 and the carrier adjusting layer 175 between the light emitting layers 164 and 165 which are coating films and the second hole transporting layer 176 which is a vapor deposition film omitted, and with the third hole transporting layer 173 between the hole injecting layer 163 and the intermediate layer 174 on the anode 24B omitted.

Since the specific configuration of each layer has been described in the second embodiment, a detailed explanation will be omitted here.

The hole injecting layer 163, the first hole transporting layer 171, and the light emitting layers 164 and 165 are respectively formed using the liquid phase process (ink jet method) and the second hole transporting layer 176, the light emitting layer 177, the electron transporting layer 178, the electron injecting layer 179, and the cathode 25 are respectively formed using the gas phase process (vapor deposition method).

### Example 18

As shown in FIG. 18, with respect to Comparative Example 5, in Example 18, the intermediate layer 174 and the carrier adjusting layer 175 are formed with the gas phase process (vapor deposition method) between the light emitting layers 164 and 165 which are coating films and the second hole transporting layer 176 which is a vapor deposition film. In addition, the third hole transporting layer 173 is formed between the hole injecting layer 163 and the intermediate layer 174 on the anode 24B. The third hole transporting layer 173 includes α-NPD as a hole transporting material of low molecular weight, and has a film thickness of 40.0 nm. The intermediate layer 174 includes CBP which is a low molecular weight host material included in the light emitting layers 164 and 165, and has a film thickness of 5.0 nm. In addition, the film thickness of the light emitting layers 164 and 165 is 55.0 nm, respectively. That is, the total film thickness of the light emitting layers 164 and 165 and the intermediate layer 174 is 60 nm. The carrier adjusting layer 175 includes cesium carbonate and the film thickness thereof is 0.5 nm.

### Example 19

As shown in FIG. 18, with respect to Example 18, in Example 19, the low molecular weight host material configuring the intermediate layer 174 is set as mCP.

### Example 20

As shown in FIG. 18, with respect to Example 18, Example 20 includes CBP and mCP as the low molecular weight host material configuring the intermediate layer 174.

### Example 21

As shown in FIG. 18, with respect to Example 18, Example 21 includes CBP and mCP which are the low molecular weight host material and Irppy3 which is the dopant as the components configuring the intermediate layer 174.

### Example 22

As shown in FIG. 18, with respect to Example 18, Example 22 includes CBP and mCP which are the low molecular weight host material, Irppy3 which is the dopant, and BAlq which is an electron transporting material as the components configuring the intermediate layer 174.

Since dark spots were confirmed when the brightness was halved without the intermediate layer 174 and the carrier adjusting layer 175 which are vapor deposition films between the light emitting layers 164 and 165 which are coating films and the second hole transporting layer 176 which is a vapor deposited film, and without the third hole transporting layer 173 between the hole injecting layer 163 and the intermediate layer 174 on the anode 24B, the evaluation of Comparative Example 5 was “X”.

Example 18 and Example 19, in which the intermediate layer 174 and the carrier adjusting layer 175 which are vapor deposition films were provided between the light emitting layers 164 and 165, which are coating films, and the second hole transporting layer 176 which is a vapor deposition film and in which the third hole transporting layer 173 including the hole transporting material of low molecular weight was provided between the hole injecting layer 163 and the intermediate layer 174 on the anode 24B, had a light emitting efficiency 1.2 times that of Comparative Example 5 while having 1.4 times the brightness half-life and dark spots were also not confirmed. In particular, the light emitting efficiency in the light emitting layer 177 was improved. In addition, by having the carrier adjusting layer 175, since changes of the light emission color of the light emitting layers 164 and 165 when the brightness is reduced by half are suppressed in order to make the transport of the electrons to the red light emitting layer 164 as the first light emitting layer and the green light emitting layer 165 as the third light emitting layer more efficient and to improve the balance of the carrier (holes and electrons) in the light emitting layers 164 and 165, the evaluation thereof is “⊙” which is excellent even in comparison with Example 13 and Example 14 of the third embodiment.

With respect to Comparative Example 5, since Example 20 to Example 22 including a low molecular weight host material of two species in the intermediate layer 174 exhibited excellent numerical values in light emitting efficiency and brightness half-life, dark spots were also not confirmed, and changes of the light emission color when the brightness is reduced by half are suppressed, the evaluation thereof is “⊙”. In particular, with respect to Comparative Example 5, Example 21 further including Irppy3, which is a dopant, in the intermediate layer 174 is particularly further improved in the light emitting efficiency in the light emitting layer 177 and is more preferable with a light emitting efficiency of 1.6 times and a brightness half-life of 1.8 times.

According to the above-described fourth embodiment, the following effects can be obtained in addition to the effects (1) to (3) of the above-described second embodiment and the effect (4) of the third embodiment.

(5) According to the organic EL apparatus 311 and the manufacturing method thereof of the fourth embodiment, since, in the blue light emitting element 327B, the third hole transporting layer 173 including the hole transporting material of low molecular weight is selectively formed by the liquid phase process between the hole injecting layer 163 which is a coating film and the intermediate layer 174 which is a vapor deposition film on the anode 24B, the transporting property of the holes to the blue light emitting layer 177 is improved, and the light emitting efficiency is improved. In other words, it is possible to provide and manufacture the organic EL apparatus 311 having the blue light emitting element 327B in which superior light emitting efficiency and brightness half-life are realized.

### Fifth Embodiment

### Configuration of Electronic Equipment

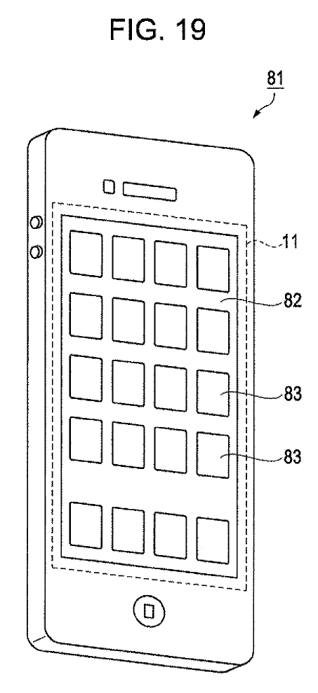

FIG. 19 is a schematic diagram showing a smartphone as an example of electronic equipment. Below, description will be given of the configuration of the smartphone provided with the above-described organic EL apparatus with reference to FIG. 19.

As shown in FIG. 19, the smartphone 81 has a display unit 82 and icons 83. The organic EL apparatus 11 of the first embodiment is incorporated in the inner portion of the display unit 82. Accordingly, it is possible to achieve a high quality display. Here, any of the organic EL apparatuses 111, 211, and 311 of the previously described second to fourth embodiments may be mounted in the display unit 82.

In addition, other than the above-described smartphone 81, examples of the electronic equipment to which any of the organic EL apparatuses 11, 111, 211, and 311 are applied include mobile phones, head-mounted displays, mini projectors, mobile computers, digital cameras, digital video cameras, vehicle equipment, audio equipment, exposure apparatuses, lighting equipment, and the like.

The invention is not limited to the above-described embodiments and is able to be appropriately changed within a range not departing from the gist or spirit of the invention read from the claims and the entire specification, and an organic EL apparatus according to such changes, a method of manufacturing the organic EL apparatus, and electronic equipment to which the organic EL apparatus is applied are also further included in the technical range of the invention. Other than the above-described embodiments, various modification examples may be considered. Below, description will be given of an example modification example.

### Modification Example 1

In the above-described fourth embodiment, it is desirable to provide the carrier adjusting layer 175; however, by providing the third hole transporting layer 173, it is possible to improve the light emitting efficiency in the blue light emitting layer 177 in comparison with the organic EL apparatus 111 of the second embodiment even when there is no carrier adjusting layer 175.

### Modification Example 2

The organic EL apparatuses 11, 111, 211, and 311 of the above-described embodiments are configured to display an image using units of pixels with a set of red (R), green (G), and blue (B) sub-pixels 34; however, the invention is not limited thereto. A configuration including sub-pixels 34 other than red (R), green (G), and blue (B), for example, yellow or orange, coating the light emitting layers of the sub-pixels 34 separately using the liquid phase process, and having the blue (B) light emitting layer formed by the gas phase process in common, may be adopted.

The entire disclosure of Japanese Patent Application No. 2012-051322, filed Mar. 8, 2012 and Japanese Patent Application No. 2012-267971, filed Dec. 7, 2012 are expressly incorporated by reference herein.

What is claimed is:

1. A manufacturing method of an organic EL apparatus provided with a plurality of light emitting elements having a light emitting layer between an anode and a cathode, the method comprising:
forming the light emitting layer using a liquid phase process; and
forming an intermediate layer between the light emitting layer and the cathode in contact with the light emitting layer using a gas phase process,
wherein the intermediate layer includes a low molecular weight host material included in the light emitting layer.

2. A manufacturing method of an organic EL apparatus provided with a first light emitting element having a first light emitting layer between a first anode and a shared cathode, and a second light emitting element having a second light emitting layer between a second anode and the shared cathode, the method comprising:
forming the first light emitting layer using a liquid phase process;
forming the second light emitting layer, which straddles the first light emitting element and the second light emitting element, between the first light emitting layer and the shared cathode and between the second anode and shared cathode using a gas phase process; and
forming an intermediate layer, which straddles the first light emitting element and the second light emitting element, between the first light emitting layer and the second light emitting layer and in contact with the first light emitting layer using the gas phase process,
wherein the intermediate layer includes a low molecular weight host material included in the first light emitting layer.

3. The manufacturing method of an organic EL apparatus according to claim 2, further comprising:
forming a hole injecting layer between the first anode and the first light emitting layer and between the second anode and the intermediate layer, in contact with the first anode and the second anode, using the liquid phase process;
forming a first hole transporting layer between the hole injecting layer and the first light emitting layer and in contact with the hole injecting layer, using the liquid phase process; and
forming a second hole transporting layer, which straddles the first light emitting element and the second light emitting element, between the intermediate layer and the second light emitting layer, using the gas phase process,
wherein the second light emitting layer is formed in contact with the second hole transporting layer.

4. The manufacturing method of an organic EL apparatus according to claim 3, further comprising:
forming a carrier adjusting layer between the intermediate layer and the second hole transporting layer in contact with the intermediate layer, using the gas phase process,
wherein the carrier adjusting layer includes a metal compound having an electron transporting property.

5. The manufacturing method of an organic EL apparatus according to claim 4, wherein the metal compound is cesium carbonate.

6. The manufacturing method of an organic EL apparatus according to claim 3,
wherein the second hole transporting layer includes a hole transporting material of low molecular weight,
the method further comprises forming a third hole transporting layer including a hole transporting material of low molecular weight between the second anode of the second light emitting element and the intermediate layer and in contact with the hole injecting layer, using the liquid phase process, and
the forming of the third hole transporting layer is performed after the step of forming the first light emitting layer.

7. The manufacturing method of an organic EL apparatus according to claim 2,
wherein the organic EL apparatus includes a third light emitting element having a third light emitting layer between the third anode and the shared cathode,
the method further comprises forming the third light emitting layer, using the liquid phase process,
the second light emitting layer is formed between the first light emitting layer and the shared cathode and between the third light emitting layer and the shared cathode, and
the first light emitting layer, the second light emitting layer, and the third light emitting layer respectively indicate different light emission colors.

8. The manufacturing method of an organic EL apparatus according to claim 7,
wherein the first light emitting layer indicating a red light emission color is formed,
the second light emitting layer indicating a blue light emission color is formed, and
the third light emitting layer indicating a green light emission color is formed.

9. The manufacturing method of an organic EL apparatus according to claim 1, wherein a thickness of the intermediate layer is 1 nm or more and 5 nm or less.

10. The manufacturing method of an organic EL apparatus according to claim 1, wherein the low molecular weight host material has an electron transporting property.

11. The manufacturing method of an organic EL apparatus according to claim 1, wherein the liquid phase process is a liquid droplet discharge method discharging a functional liquid including a functional layer forming material as the liquid droplets.

12. An organic EL apparatus comprising:
on a substrate,
an anode,
a cathode which is a vapor deposited film,
a light emitting layer which is a coating film between the anode and the cathode, and
an intermediate layer, which is a vapor deposited film including a low molecular weight host material included in the light emitting layer, between the light emitting layer and the cathode and in contact with the light emitting layer.

13. An organic EL apparatus comprising:
on a substrate,
a first light emitting element having a first light emitting layer which is a coating film and a second light emitting layer which is a vapor deposited film between a first anode and a shared cathode which is a vapor deposited film,
a second light emitting element having a second light emitting layer between the second anode and the shared cathode, and
an intermediate layer, which is a vapor deposited film including a low molecular weight host material included in the first light emitting layer and which is formed to straddle the first light emitting element and the second light emitting element in contact with the first light emitting layer between the first light emitting layer and the second light emitting layer and between the second anode and the second light emitting layer.

14. The organic EL apparatus according to claim 13 further comprising:
a hole injecting layer, which is a coating film, between the first anode and the first light emitting layer and between the second anode and the intermediate layer in contact with the first anode and the second anode,
a first hole transporting layer, which is a coating film, between the hole injecting layer and the first light emitting layer in contact with the hole injecting layer, and
a second hole transporting layer, which is a vapor deposited film, between the intermediate layer and the second light emitting layer.

15. The organic EL apparatus according to claim 13, further comprising:
a carrier adjusting layer, which is a vapor deposited film, between the intermediate layer and the second hole transporting layer in contact with the intermediate layer,
wherein the carrier adjusting layer includes a metal compound having an electron transporting property.

16. An organic EL apparatus according to claim 13,
wherein the second hole transporting layer includes a low molecular weight hole transporting material, and
the apparatus further comprises a third hole transporting layer including the low molecular weight hole transporting material, which is a coating film, between the second anode of the second light emitting element and the intermediate layer in contact with the second anode.

17. The organic EL apparatus according to claim 13, further comprising:
a third light emitting element having a third light emitting layer, which is a coating film, between the third anode and the shared cathode,
wherein the second light emitting layer is formed between the first light emitting layer and the shared cathode and between the third light emitting layer and the shared cathode, and
the first light emitting layer, the second light emitting layer and the third light emitting layer respectively indicate different light emission colors.

18. The organic EL apparatus according to claim 17,
wherein the first light emitting layer of the first light emitting element indicates a red light emission color,
the second light emitting layer of the second light emitting element indicates a blue light emission color, and
the third light emitting layer of the third light emitting element indicates a green light emission color.

19. Electronic equipment comprising:
an organic EL apparatus manufactured using the manufacturing method of an organic EL apparatus according to claim 1.

20. Electronic equipment comprising:
the organic EL apparatus according to claim 12.
